(19) United States
(12) Patent Application Publication
(10) Pub. No.: US 2025/0011162 A1
(43) Pub. Date: Jan. 9, 2025

(54) Suspension for Resonators and MEMS Devices

(71) Applicant: SiTime Corporation, Santa Clara, CA (US)

(72) Inventors: Nicholas MILLER, Dexter, MI (US); James Howard Thomas RANSLEY, Medford, MA (US); Paul M. HAGELIN, Saratoga, CA (US); Markus LUTZ, Mountain View, CA (US)

(21) Appl. No.: 18/712,420

(22) PCT Filed: Dec. 22, 2022
(86) PCT No.: PCT/US2022/053788

§ 371 Date: May 22, 2024

Related U.S. Application Data
(60) Provisional application No. 63/295,708, filed on Dec. 31, 2021.
(60) Provisional application No. 63/313,218, filed on Feb. 23, 2022.
(60) Provisional application No. 63/411,744, filed on Sep. 30, 2022.

(51) Int. Cl. B81B 7/00; H03H 9/02; H03H 9/09

(52) U.S. Cl. CPC B81B 7/0058; H03H 9/02448; H03H 9/09; B81B 2201/0271; B81B 2203/0163; B81B 2207/012; B81B 2207/07

(57) ABSTRACT

A resonator and/or MEMS device is provided with a flexible suspension mount to reduce mechanical stress and/or interference arising from other electrical components. In one illustrative embodiment, the flexible suspension mount can be configured as one or more metallic springs that provide for electrical connection as well as for specific spring and dampening coefficients. In another illustrative material, techniques can be use which change spring and/or dampening coefficients at a particular point in the manufacturing/assembly/distribution process, optionally before device characterization and/or programming.

### REFERENCE TO RELATED APPLICATIONS

This patent application is a US National Stage entry, filed under 35 USC 371, of International Application No. PCT/US2022/053788 (published as WO2023/129468A1), filed on 22 Dec. 2022 on behalf of first-named inventor Nicholas MILLER, for “Suspension For Resonators and MEMS Devices,” which in turn claims the benefit of the following US Provisional Patent Applications: (1) No. 63/295,708, filed on Dec. 31, 2021, on behalf of first-named inventor Nicholas Miller, for “Manufacturing, packaging and assembly for dies having MEMS devices;” (2) No. 63/313,218, filed on Feb. 23, 2022, on behalf of first-named inventor James Howard Thomas Ransley, for “Shape-morphing die attach;” and (3) No. 63/411,744, filed on Sep. 30, 2022, on behalf of first-named inventor Nicholas Miller, for “Manufacturing, packaging and assembly for dies having MEMS devices. Each aforementioned domestic and/or international patent application is hereby incorporated by reference.

### TECHNICAL FIELD

This disclosure relates to design, manufacturing, assembly, transport and operation of integrated circuit devices, particularly oscillators and devices that use some type of deflecting or vibrating electromechanical component, for example, but not limited to, microelectromechanical systems (“MEMS”) devices and certain types of electronic sensors.

### BACKGROUND

Recent years have seen the development of digital technologies that incorporate some type of deflecting or vibrating circuit level component. For example, digital systems typically rely on a quartz resonator to generate a timing signal used to drive digital operations; such a resonator is typically mounted by, or in close proximity to, a printed circuit board (“PCB”). Other systems feature small moving bodies that sense or react to environmental parameters such as, for example, circuit board level pressure, temperature, and inertial sensors. These devices typically feature some type of body which vibrates or deflects to an extent associated with some type of parameter that is to be sensed. Still more recently, advances in semiconductor manufacture has seen process developments that permit the building of some of these devices as a direct part of a die or integrated circuit, i.e., sometimes these devices are grown or etched as part of the integrated circuit building process. For example, integrated circuits can be manufactured which feature mounted quartz resonators, microelectromechanical systems (“MEMS”) resonators, MEMS pressure sensors, MEMS inertial sensors, MEMS temperature sensors and other types of digital components that feature some type of vibrating or deflecting structure.

Unfortunately, as the size of these devices become smaller, and as they are integrated into digital systems, it becomes difficult to isolate the devices from mechanical disturbances which can influence their operation. These disturbances can occur randomly, for example, after distribution of a consumer product, but particularly troublesome are disturbances which occur as part of planned operation of the device or during the manufacturing process, and which can therefore shift device performance by loosening mounts and otherwise shifting device performance. As nonlimiting examples of these problems, vibrations from other PCB and/or product components can interfere with operation of MEMS devices and resonators by contributing unwanted harmonics or contributing various types of noise; sometimes also, these devices are calibrated or otherwise programmed during manufacture in a manner which, if the system then experiences shock (e.g., manufacturing during electrical connection and/or product assembly) can result in aberrant performance.

What is needed is a set of techniques for addressing these problems and/or providing assembly processes which are robust to these types of stresses and/or disturbances. The present invention solves these needs and provides further, related advantages.

### BRIEF DESCRIPTION OF THE DRAWINGS

FIG. 1 is an illustrative diagram used to explain one embodiment of an electronic device having a flexible suspension mount, intended to reduce the impact of mechanical stress.

FIG. 2A is a diagram showing one configuration of an integrated circuit (“IC”) or other electrical device which embodies techniques described herein.

FIG. 2B is a diagram showing another configuration of an IC or other electrical device which embodies techniques described herein.

FIG. 2C is a diagram showing one configuration of an IC or other electrical device which embodies techniques described herein.

FIG. 2D is a diagram showing another configuration of an IC or other electrical device which embodies techniques described herein.

FIG. 2E is a diagram showing another configuration of an IC or other electrical device which embodies techniques described herein.

FIG. 2F is a diagram showing one configuration of an IC or other electrical device which embodies techniques described herein.

FIG. 2G is a diagram showing another configuration of an IC or other electrical device which embodies techniques described herein.

FIG. 3A is an illustrative diagram used to explain some of the techniques described herein.

FIG. 3B is a graph which shows peak shock response and mechanical stress attenuation provided by a flexible suspension mount as a function of mount suspension frequency.

FIG. 4A is an illustrative diagram which shows techniques used in connection with another embodiment described herein. An IC can be manufactured with a flexible suspension mount as well as with a protective polymer used to protect the flexible suspension mount until packaging, assembly and/or distribution, after which the protective polymer can be removed.

FIG. 4B is a three-dimensional perspective view of another embodiment, in which an IC has a four pin connection that provides a flexible suspension mount.

FIG. 4C shows a photo of a redistribution layer (“RDL”) arrangement and some close-up detail for the flexible suspension mount from FIG. 4B.

FIGS. 5A-5L show a sequence of semiconductor process steps. Shading used in these various FIGS. is occasionally changed emphasize certain steps and/or structures being discussed for a particular FIG.

FIG. 5A shows a die or substrate 501 having metal contact pads 503 and 505.

FIG. 5B shows the die/substrate of FIG. 5A after a protective layer and sacrificial layer have been deposited.

FIG. 5C shows the die/substrate of FIG. 5B after deposition of a mask seed layer.

FIG. 5D shows the die/substrate of FIG. 5C after performance of a copper plating step.

FIG. 5E shows the die/substrate of FIG. 5D after deposition of a mask for stud plating.

FIG. 5F shows the die/substrate of FIG. 5E after performance of another metal plating step.

FIG. 5G shows the die/substrate of FIG. 5F, with a mask layer 523 deposited to define reception points for first solder bumps 525.

FIG. 5H shows the first/substrate of FIG. 5G, where the mask layer from FIG. 5G has now been removed, and where conductive adhesive bumps 527 have now been dispensed.

FIG. 5I shows attachment of a second die/substrate 529, with electrical interconnection between being established by the conductive adhesive bumps 527 from FIG. 5H.

FIG. 5J shows the two die/substrate structure from FIG. 5I, but with sacrificial layers now removed.

FIG. 5K shows flip-chip attachment of the two die/substrate structure from FIG. 5J onto a supporting frame, die or another type of substrate 533.

FIG. 5L shows the addition of a peripheral seal 541 to encapsulate the second die (529), relative to the first die (501).

FIG. 6A shows another embodiment of a flexible suspension mount; the flexible suspension characteristics in this embodiment is provided by a combination of flexible layer 607 and nonrigid electrical interconnections 609 (e.g., which can include, but are not limited to, wire bonds, or a leaf-spring connection). The layer 607 can be selected to have specific rigidity characteristics as well as specific frequency dampening characteristics. One optional implementation of layer 607 is as an expanding material, such as an expanding foam.

FIG. 6B shows the structure from FIG. 6A, but after the layer 607 has expanded and changed its resiliency characteristics (e.g., spring constant and dampening coefficients), as indicated by expansion arrows 607.

FIG. 6C shows a structure similar to the one seen in FIG. 6A, but where the flexible suspension mount of some earlier-described embodiments is used in combination with an expanding material (i.e., layer 607), to prestress the flexible suspension mount.

FIG. 6D shows another embodiment, similar to the one seen in FIG. 6C, but where the expanding material of layer 607 is used on an opposite side of die 613, to prestress the flexible suspension mount.

FIG. 6E shows a structure, similar to the one seen in FIG. 6D, but where an expanding layer 607 is used in combination with another material, e.g., a gel, oil or adhesive 629.

FIG. 7A is a graph that shows first principle stress as a function of ratio of connection surface area to die surface area. A data plot 703 shows that the average first principle stress decreases as the surface area of mechanical interconnection becomes small (e.g., relative to MEMS die surface area).

FIG. 7B is a perspective diagram used to illustrate a surface area of interconnection between a first die/substrate 713 and a second die/substrate 715.

FIGS. 8A-8E are used to illustrate a manufacturing technique whereby a connecting material is initially included, but then subsequently released, to permit shape morphing of a die attach structure and reconfiguration of flexible suspension properties.

FIG. 8A shows die/substrate attachment using an adhesive tape 804.

FIG. 8B shows attachment of wire bonds or other electrical interconnections 815 following mechanical attachment of dies/substrates 803 and 805.

FIG. 8C shows release of a temporary structure, which permits layer 807 to expand, as indicated by arrows 817.

FIG. 8D is similar to FIG. 8C, but which shows an adhesive material 819 on an opposite side of an expanding material layer 807.

FIG. 8E shows an embodiment where some or all of the release structure 809 remains in the manufactured assembly following release.

FIG. 9A shows an embodiment where the temporary structure 909 is used to help support a die 903 on a substrate.

FIG. 9B shows an embodiment 911, similar to the embodiment of FIG. 9A, but where the temporary structure 909 has been removed; in this embodiment, material 907 is an expanding material that morphs and, in so doing, changes suspension characteristics of the die's mounting.

FIG. 9C shows an embodiment where temporary structures 909 remain in the assembly following release.

FIG. 9D shows an embodiment 931, similar to the embodiment of FIG. 9A, but where the temporary structure has been removed (with space formerly occupied by the temporary structure designated by numeral 909′.

FIG. 9E illustrates use of a die attach film and dicing process.

FIG. 10A illustrates a pattern that can be used for reduced area mechanical suspension, e.g., based on the use of one or more permanent layers or structures and/or one or more temporary structures, as described in connection with FIGS. 7-9E. Dark-colored shading can either represent such layers or structures, or the absence of such layers or structures.

FIG. 10B illustrates another pattern.

FIG. 10C illustrates another pattern.

FIG. 10D illustrates another pattern.

FIG. 10E illustrates another pattern.

FIG. 10F illustrates another pattern.

FIGS. 11A-11E are used to illustrate some optional packaging techniques.

FIG. 11A illustrates a structure where a glob (e.g., gel, resin, plastic or other material) is used to encapsulate a first die/substrate 1103 relative to a second die/substrate 1105.

FIG. 11B illustrates another structure where a glob (e.g., gel, resin, plastic or other material) is used to encapsulate a first die/substrate 1103 relative to a second die/substrate 1105.

FIG. 11C illustrates an embodiment where two dies/substrates are mounted within a cavity wafer 1123 having a lid 1125.

FIG. 11D shows an embodiment similar to the one seen in FIG. 11C, but where one of the dies/substrates serves as a lid.

FIG. 11E shows a packaging arrangement where two dies/substrates are mounted by a lead frame 1142, which is then encapsulated in plastic 1149.

FIG. 12A is a hardware block diagram showing components in one embodiment of an IC or die.

FIG. 12B is a flowchart of a method which is optionally be used in some embodiments.

The subject matter defined by the enumerated claims may be better understood by referring to the following detailed description, which should be read in conjunction with the accompanying drawings. This description of one or more particular embodiments, set out below to enable one to build and use various implementations of the technology set forth by the claims, is not intended to limit the enumerated claims, but to exemplify their application. Without limiting the foregoing, this disclosure provides several different examples of techniques that can be used to provide a flexible suspension mount for one or more dies, integrated circuits (“ICs”), printed circuit boards (“PCBs”) and/or to support some other form of electric substrate. As indicated earlier, an electrical component used in such a device can have one or more deflecting or vibrating structures, each for example being resonator and/or a MEMS device. Generally speaking, these techniques can also be applied to mounting of quartz crystal and to devices other than resonators and other than MEMS devices; without limiting the foregoing, it is believed that applications of these techniques exist for, e.g., temperature sensors, pressure sensors, inertial sensors, and so forth. Optional methods of manufacture, assembly and operation are also described, including without limitation, a method where temperature compensation data is learned or programmed at a specific step or milestone in a manufacturing process. Generally speaking, the described techniques provide for a more reliable and/or more accurate device performance and/or manufacturing and assembly processes which support better device reliability. While specific examples are presented, the principles described herein may also be applied to other methods, devices and systems as well.

### DETAILED DESCRIPTION

This disclosure provides techniques for addressing the aforementioned problems.

In one embodiment, a flexible suspension mount supports a vibrating or deflecting component on a substrate of an electrical device, such as, for example, on a printed circuit board, on a die, on an integrated circuit, etc. In this embodiment, the flexible suspension mount can be designed to provide a suspension frequency that will dampen anticipated vibration, and thereby reduce or eliminate the effect of that vibration on short or long term electrical performance of that component. While the mounted component can be any electrical device or integrated circuit, in certain designs, the mounted component can be a resonator and/or a MEMS device; for example, it can be a quartz crystal used for timing, it can be a MEMS resonator, or it can be another type of MEMS device (e.g., used as part of a pressure sensor, temperature sensor, inertial sensor, or other device, whether or not based on a resonator). Using the described techniques to relieve, isolate or dampen mechanical stress, while at the same time maintaining a desired amount of stiffness in the suspension, the techniques described herein facilitate (a) suppression of manufacturing stress on the mounted component, (b) suppression of operational stress, for example, arising from other electronic components which vibrate, and (c) improve device accuracy and reliability.

It should therefore be apparent that this disclosure provides for improvements in certain types of digital devices and semiconductor technologies.

In some embodiments, the flexible suspension mount is designed to operate much like a shock absorber, with vibrational parameters that are carefully selected to dampen commonly experienced vibrational disturbances, but also to provide mechanical stiffness suitable for other practical consideration such as handling, processing and assembly.

Note that in recent years, MEMS technology has improved to the point where resonators, pressure sensors, temperature sensors and inertial devices can be manufactured entirely using semiconductor fabrication techniques, e.g., these and other sensors and/or electrical devices can be made as integrated circuits or parts thereof. Close integration of these devices with digital systems has also created design challenges, however; in particular, the needed electrical connections to these parts are conventionally rigid, and readily couple mechanical stresses directly to the supported component, which can give rise to the problems discussed earlier. The mechanical stresses, as noted, and without limitation, can arise during manufacturing (e.g., assembly, mounting and/or mechanical interconnection processes), and/or from “live” operation of other electrical components in a digital system (e.g., which can create vibrations which might conventionally be transferred to the mounted component through solder mounts). In one noted example, vibration can be generated by certain types of ceramic capacitors, which exhibit a piezoelectric effect that transduces electrical signals into mechanical vibration. This mechanical vibration can affect the operation of other devices, possibly reducing performance and causing malfunction. For example, this mechanical vibration can inhibit accurate detection of resonance frequency and can cause certain types of phase and other measurement noise.

To counteract these effects, the flexible suspension mount can be designed to have a suspension frequency that dampens or isolates specific unwanted harmonics to a degree where those harmonics become insignificant. To cite a specific example which will be reused below, in one embodiment, if an oscillator is subject to a potentially-interfering oscillation frequency of 500 kilohertz (“kHz”), and a suspension frequency of 50 kHz is used, such provides 100× suppression of the vibrational frequency, which it dampens according to the square of the ratio of the two frequencies, and if the suspension frequency is increased to 90 kHz, a suppression of approximately 30.86× (i.e., (500/90)²) is obtained; by tailoring suspension frequency of the flexible suspension mount to suppress a specific target frequency (e.g., a 500 kHz short-term disturbance in this example), the flexible suspension mount provides significant suppression of this specific frequency while at the same time providing mount stiffness robust to other types of motion.

A number of specific further embodiments will be described below. In a first case, a flexible suspension is provided by one or more structures that perform double duty for both mechanical support and electrical connection. For example, electrical interconnections can be designed to operate as mechanical springs (e.g., shock absorbers), while providing for continued electrical interconnection. Nearly any type of spring design or structure can be used, including without limitation, a design premised on one or more leaf spring or coil spring-like structures. In a second example, a flexible material, such as a tape, gel, adhesive or oil can be used to provide for primary mechanical load support, with electrical connections being separate established (e.g., by one or more separate structures, such as without limitation wirebond attachments). In still further variations, a protective and/or release layer can optionally be provided, to lend mechanical stiffness during manufacturing, assembly and/or transport, but which is then removed or release so as to activate the flexible suspension mount to adopt the desired form; note that such a design may help reduce or avoid “settling effects,” e.g., where a device with expected behavior experiences post-fabrication ‘creep’ that changes expected performance parameters, and/or where the occurrence of settling might obfuscate device characterization and/or programmed parameters. Note that a protective/release layer, and associated techniques for shape morphing or suspension morphing, are not required for all embodiments.

In still other embodiments, these techniques can be combined with other structures and processes used to fabricate components/devices of the type described. As a non-limiting example, a specifically contemplated embodiment features a two-die MEMS oscillator, that is, with one or more MEMS resonators on a first die, with support circuitry on a second die, and with thermal cycling performed after packaging to learn temperature-dependent variation of the oscillator and to program correction factors into circuitry on the second die; in manufacture and/or use, a protective layer included at time of manufacture can be engaged or released after the dies are mounted, with an in-situ heating element then being selectively-actuated, during a calibration step, to cycle the assembly through a normal operating temperature range. The post-released device can thereby be characterized and programmed in-situ in a manner that follows most ordinary manufacturing-related stresses, with characterization and/or device parameters being calibrated and/or learned only after a protective/release layer has been disengaged (i.e., and/or the flexible suspension mount has assumed a desired form, that is, with desired suspension properties).

These and other benefits, and other optional techniques, will be apparent from the discussion below. Note that some embodiments discussed below provide for an already-deployed flexible suspension mount for one or more components, which accomplishes objectives set forth herein, while others use a release structure which permits later-deployment of the flexible suspension mount, e.g., to protect a manufactured device during manufacturing steps and/or periods leading up to assembly and/or device manufacture.

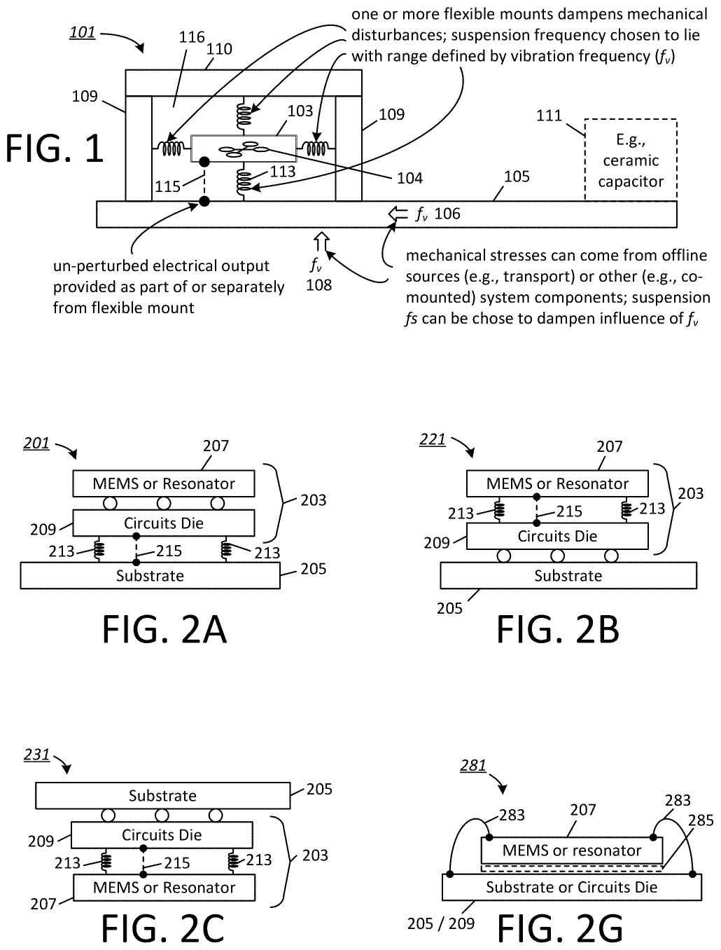

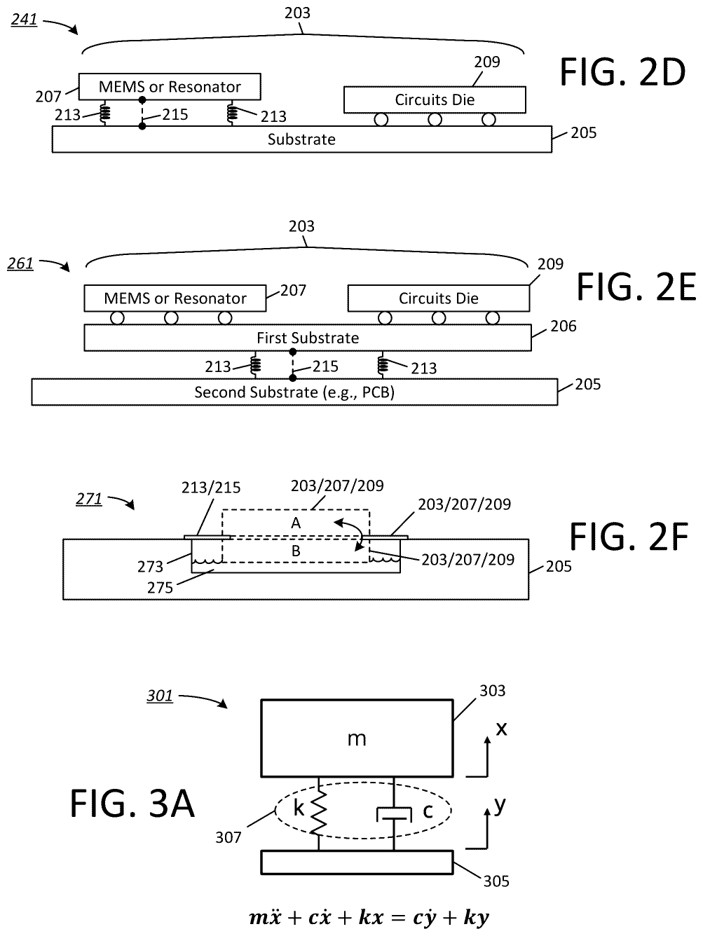

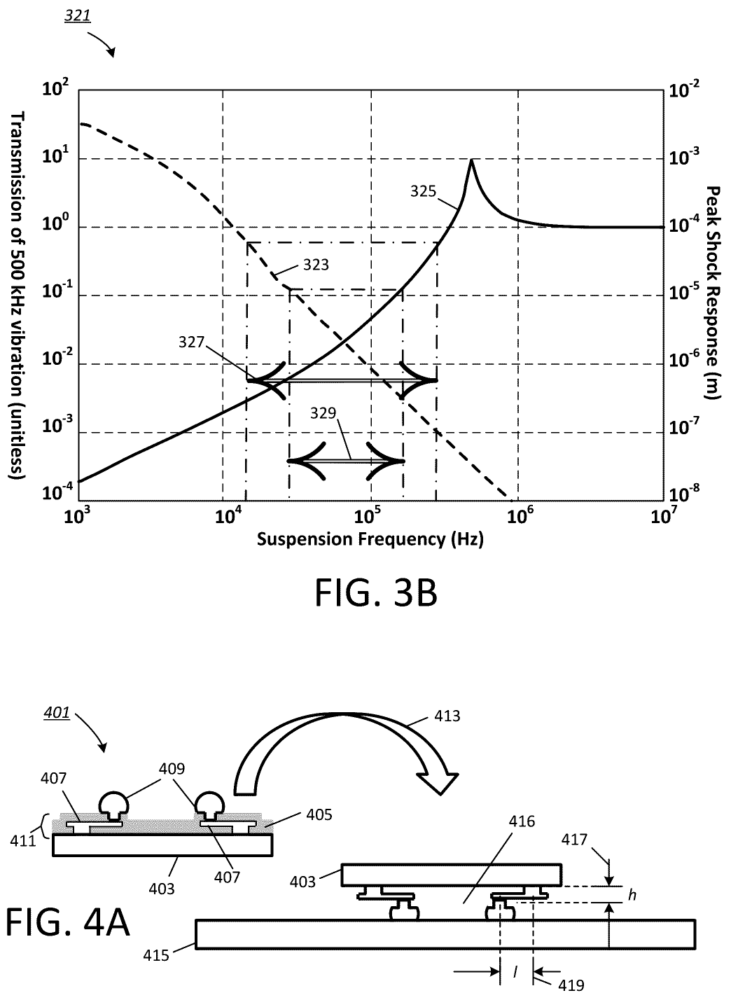

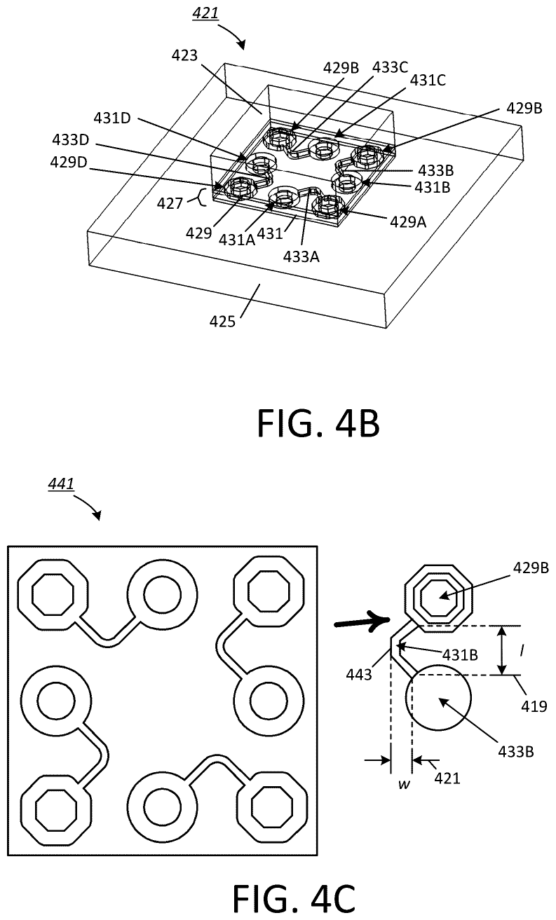

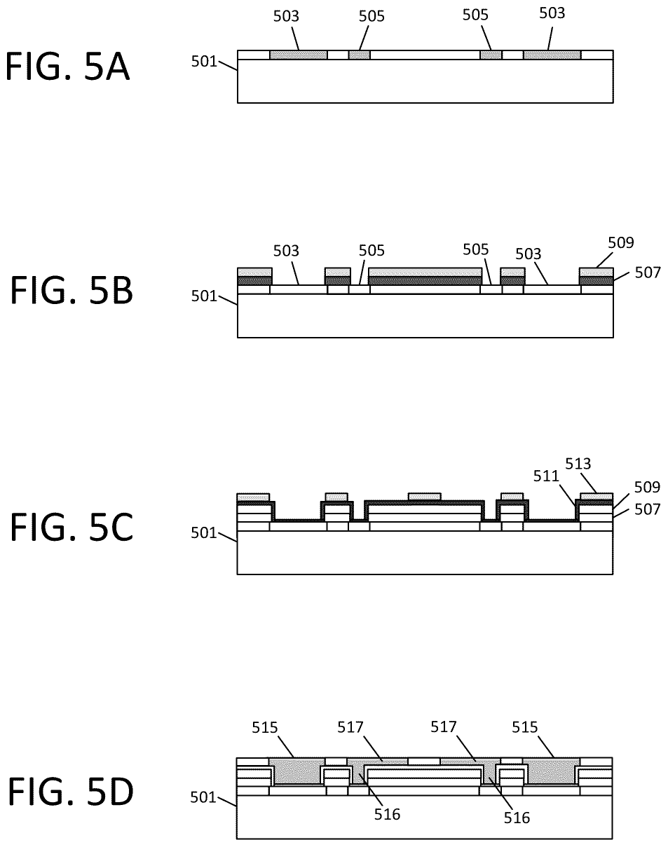

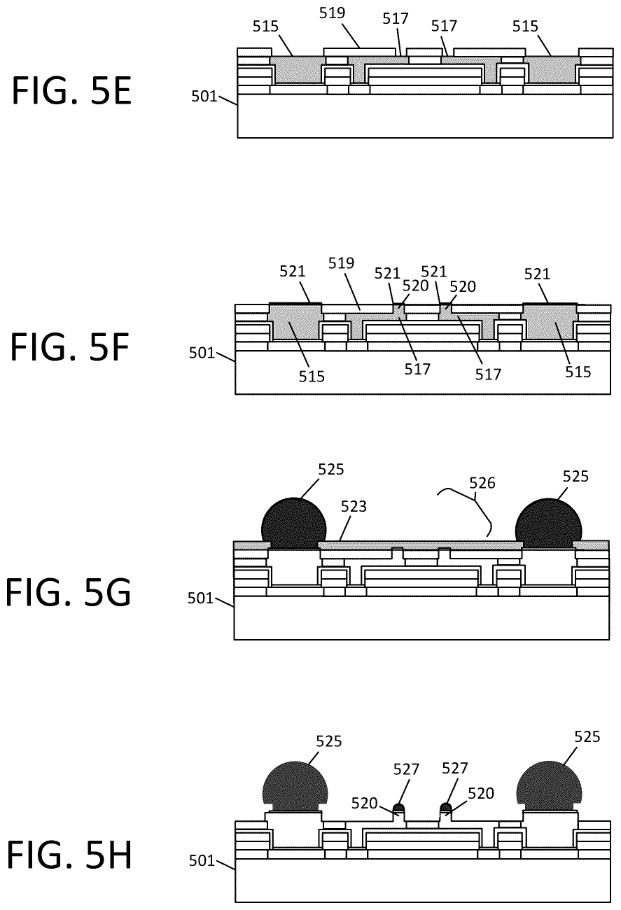

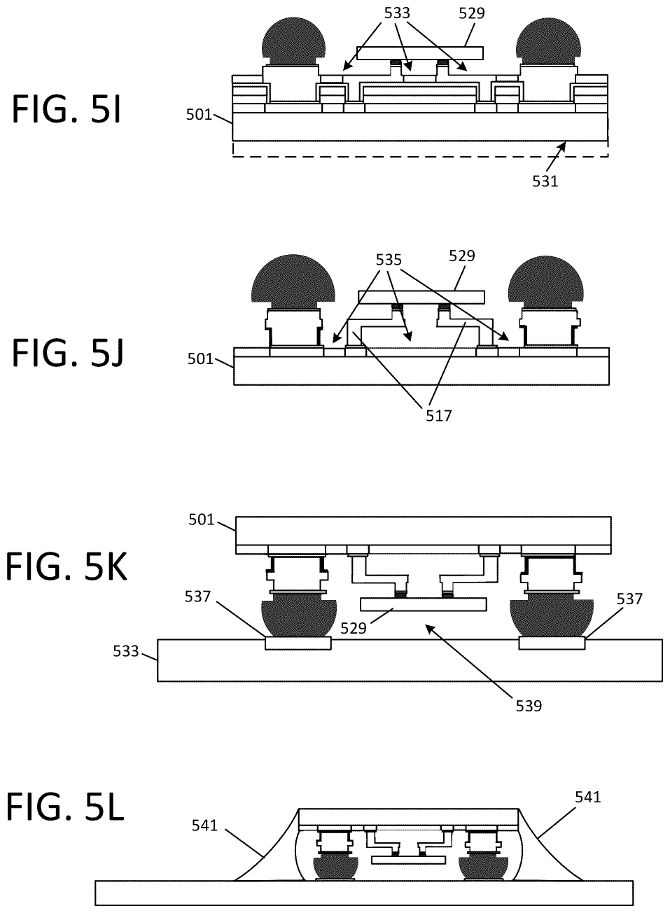

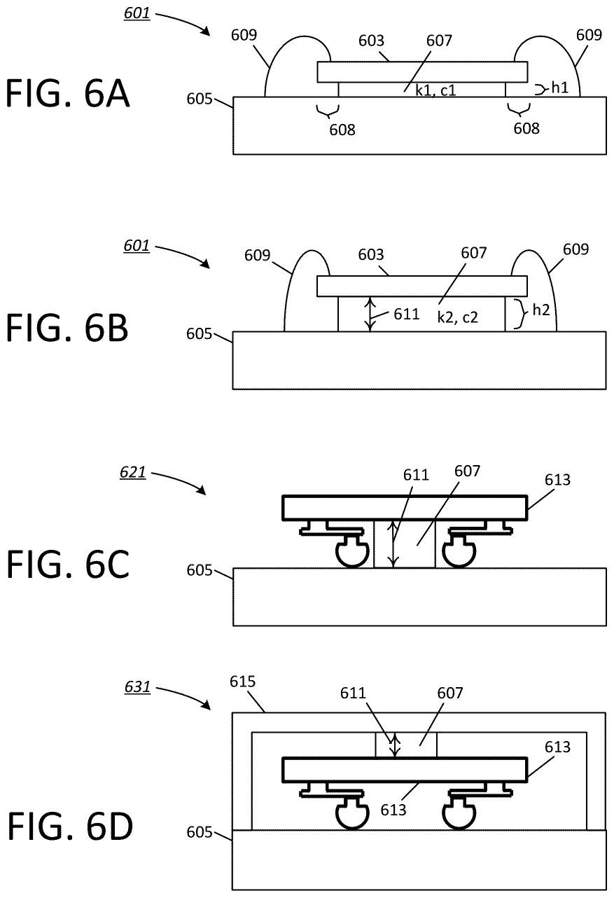

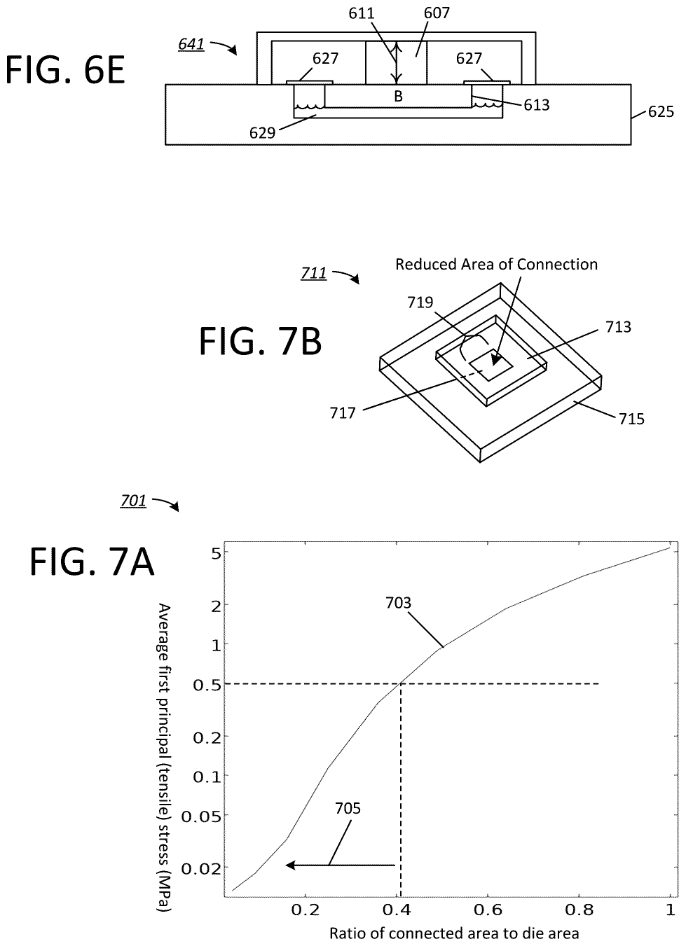

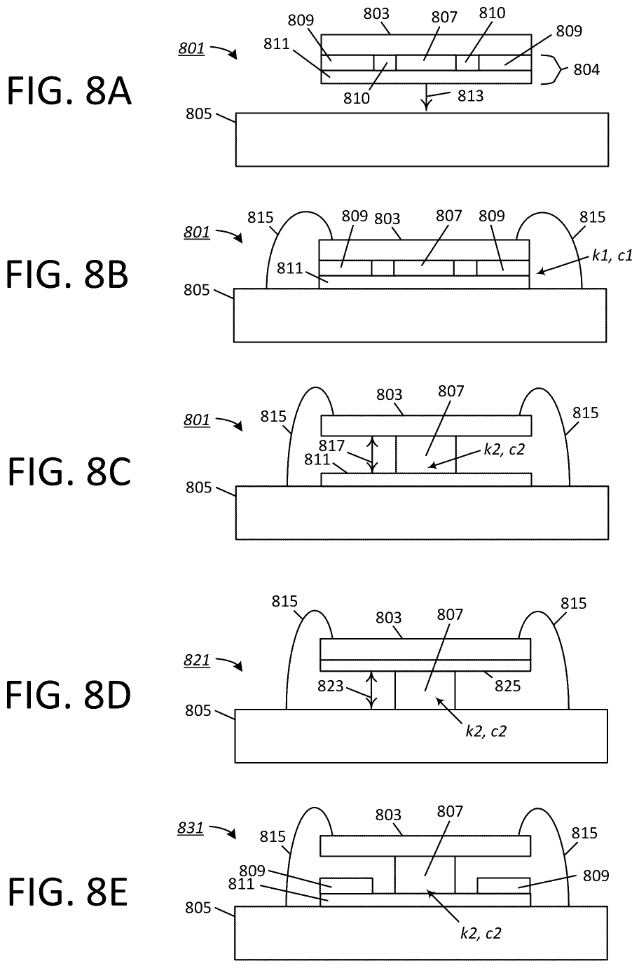

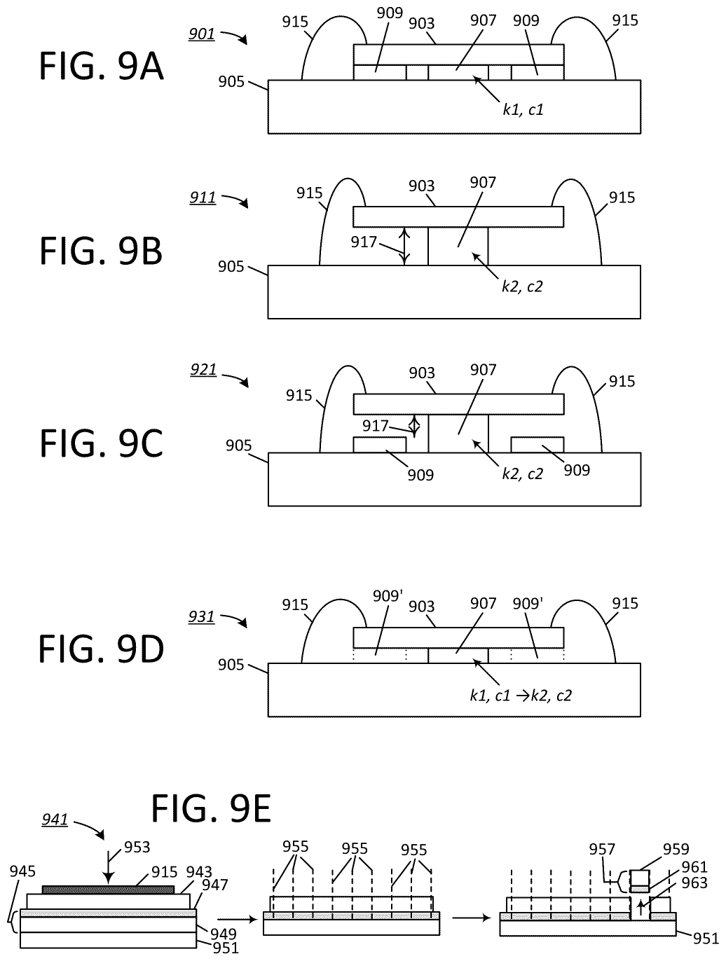

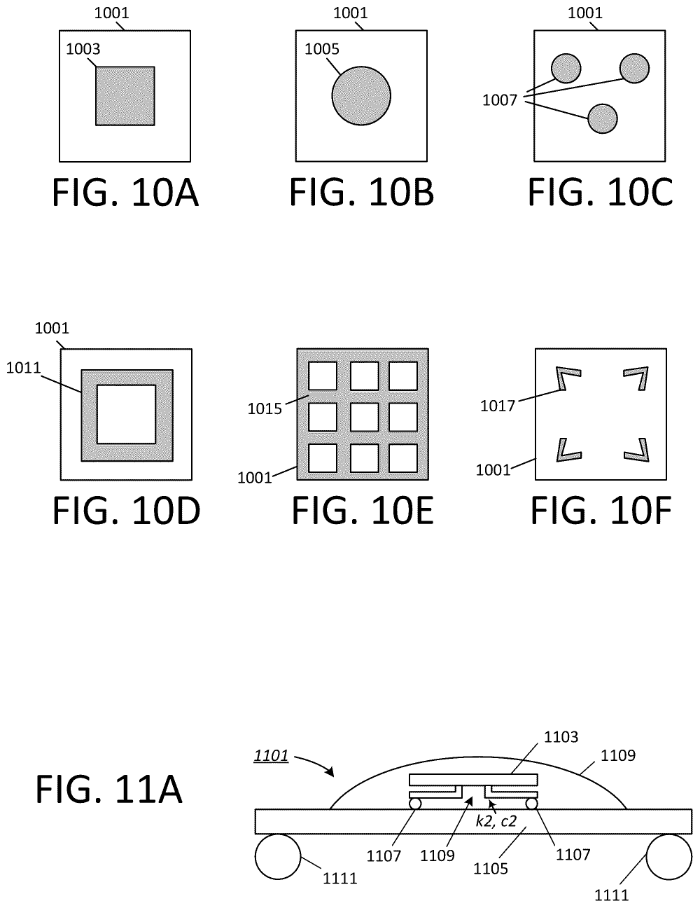

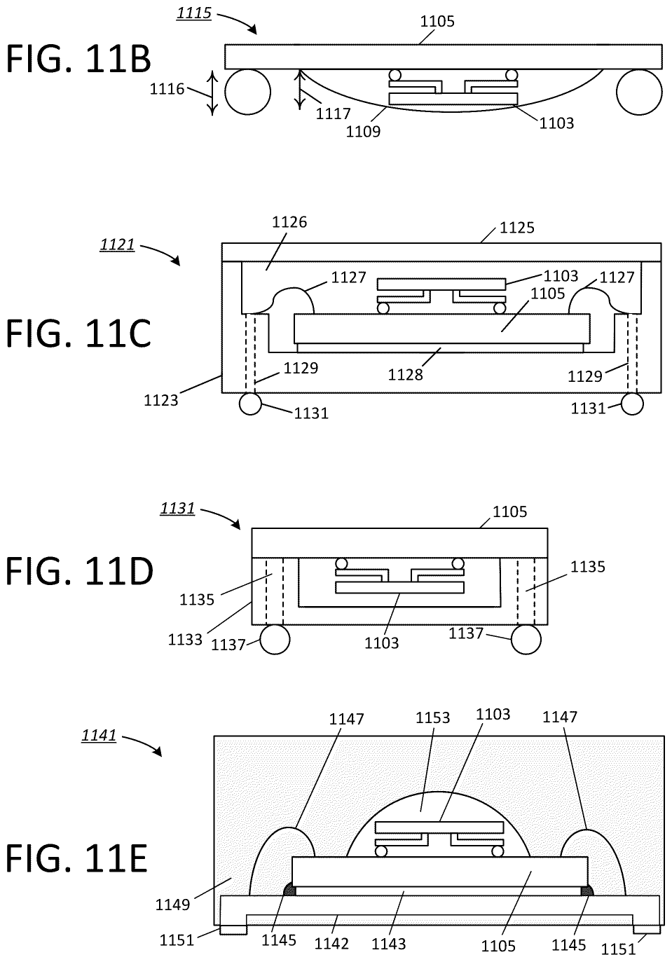

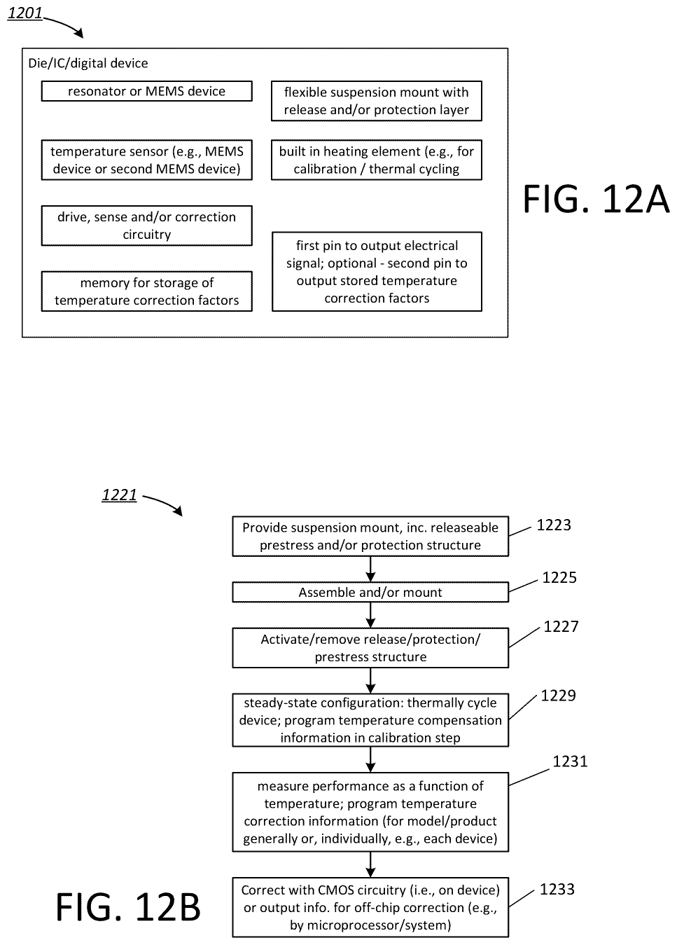

This disclosure will generally be organized as follows: FIGS. 1-2G will be used to introduce some basic embodiments and/or principles. FIGS. 3A-4C will be used to discuss design criteria for some specific applications, in particular, a MEMS resonator application. FIGS. 5A-5L will be used to discuss specific manufacturing steps that can optionally be used for structures introduced by FIGS. 4A-4C. FIGS. 6A-6E will be used to discuss embodiments where an expanding material, such as, but not limited to, an expanding foam, is used as part of flexible suspension mount. FIGS. 7A-7B are used to illustrate how variation in connection surface area can influence transmission of mechanical disturbance to a MEMS die and/or resonator. FIGS. 8A-8D will be used to discuss embodiments which use an adhesive tape for mounting, once again, in a manner that can provide for flexible suspension and/or support structure shape morphing. FIGS. 9A-9E will be used to discuss an embodiment where a temporary structure is used (e.g., as part of a semiconductor deposition or die attach process), and is subsequently etched or otherwise removed, so as to change suspension characteristics. FIGS. 10A-10F will be used to exemplify some illustrative patterns that can be used to restrict die contact area and/or provide for release and/or expansion mechanisms. FIGS. 11A-11E illustrate some optional encapsulation options. Finally, FIGS. 12A-12B will be used to discuss device characterization and programming methods (e.g., suspension release, and subsequent thermal characterization during or subsequent to manufacturing).

FIG. 1 is an illustrative diagram which shows a basic embodiment 101 of an electronic device. The electronic device has a component 103 having an element 104 which is sensitive to mechanical stress and/or vibration, such as for example, a resonator or a MEMS sensor of some type (inertial, pressure, temperature, etc.). The component is mounted to some type of substrate 105 used in an electrical device of some type, and conventionally would be rigidly mounted to this substrate, e.g., using solder mounts. In certain embodiments, the component is optionally a die and/or an integrated circuit. The substrate 105 can also optionally be in the form of an integrated circuit (e.g., a package or unpackaged structure, such as a die), but in other designs, the substrate can be a printed circuit board, or a lead frame, or some other type of conventional electronic circuit support structure. The electronic component is also seen to be encapsulated, e.g., by side walls 109 and a lid 110, though this is also not required for all embodiments.

It is assumed that component 103 is subject to mechanical disturbances which might affect or shift the operation of the component. These disturbances can be manufacturing or other stresses. For example, numeral 106 designates mechanical stress that arises from another part of the electronic device, for example but not limited to, the depicted ceramic capacitor 111. This mechanical stress is modeled here as a vibrational frequency fᵥ, however, it should be observed that the techniques disclosed herein are not limited to situations where vibrational stress and or stress that manifests as a set of one or more discrete harmonics (indeed, as is known to those familiar with mathematics or physics, even a square wave pulse can be modeled as a superposition of respective harmonics). FIG. 1 also shows a second form of mechanical stress 108, e.g., manufacturing-induced stress, also modeled as a vibrational frequency (fᵥ); the represented vibrations may be the same or different than stress 106 in terms of harmonics, frequencies, durations and/or amplitudes; this second form of mechanical stress 108 is presumed to originate somewhere else than another electronic circuit of the device. Note that steady-state or quasi-static stresses are included in the discussion as vibration at zero frequency (fᵥ=0). For example, static bending of the substrate 106 is analogous to dynamic bending and identical in the limit that the vibration frequency tends to zero.

In this design, however, the component 103 is seen to be operatively mounted by one or more flexible suspension mounts 113 to substrate 105; these are depicted as springs or absorbers in the FIG., and while four such mounts are depicted, it is noted that only one of these is numbered with a reference numeral (113). By “operatively mounted,” it is meant that the flexible suspension mount is positioned somewhere in between the component 103 and substrate 105, e.g., there may be one or more intermediate or other supports, mounts or other structures “in-line” between these the component and the substrate, and the two may not connect to each other or to the one or more flexible suspension mounts directly. As observed, in this embodiment, one or more of the flexible suspension mounts each serve double-duty in providing a mechanical coupling between the component 103 and the substrate 113 as well as providing for electrical interconnection between the two. However, this is not required for all embodiments, and it is possible to have separate electrical connections, as symbolically represented by dashed line connection 115. It should also be noted that FIG. 1 shows four springs that represent alternative and/or redundant connections, i.e., denoting that the component may be mounted underneath the substrate or another structure (e.g., in this case, lid 110 as depicted in the FIG), on top of the substrate or another structure, laterally from one or more side walls 109, or in some other manner.

In one embodiment, the component 103 comprises a quartz crystal resonator and provides an electrical output generated as a function of sensed resonance frequency of a quartz crystal; this output is represented by numeral 115 in the FIG. In other embodiments, however, component 103 is an integrated circuit that includes one or more embedded MEMS resonators, for example, electrostatic and/or piezoelectric resonators fabricated to include at least one layer of doped crystal silicon. In other embodiments, there can be two or more resonators and more than two signals; for example, it is known to use two MEMS resonators with different temperature coefficients of frequency (“TCF”) such that one of the two resonators produces a resonant frequency that varies (preferably linearly) with temperature, while the other provides a primary oscillation signal that is corrected to produce a temperature-invariant timing signal; in such a system, two electrical output signals can be produced, with frequency differences and/or ratios used as an accurate indicator of temperature. It is also possible to use MEMS resonators are pressure, inertial and/or other types of sensors, or alternatively, other types of MEMS sensors. In one embodiment, signal 115 actually denotes two or more signals (e.g., a drive signal and/or a sense signal), which can be interconnected between the component and substrate using one or more of the depicted flexible suspension mounts 113; one of these signals can also be a temperature signal. As will be disclosed for some embodiments further below, in yet other embodiments, component 103 can also include a built-in heating element, or a heating element can be included within the depicted chamber 116, so as to facilitate in situ calibration/characterization of performance of the component, e.g., at a specific point in the manufacturing, assembly and/or distribution process. These and other options will be discussed in more detail below.

Note that, as contrasted with a conventional design, the flexible mounts are designed to provide some stiffness but also to have vibrational characteristics that will dampen external mechanical disturbances. In some embodiments, these vibrational characteristics are designed so as to have a predetermined relationship to one or more specific vibrational frequencies that are used to model expected mechanical disturbances; for example, some manufacturing standards provide that integrated circuits should be tested against specific perturbations (e.g., a half-sine wave perturbation as in MIL-STD-883 Method 2002.4). In other embodiments, these vibrational characteristics are designed so as to have a predetermined relationship to deflection or vibration of a structure in the electronic device, e.g., vibrational frequency of another component, or expected motion. The result, as represented by text legends represented in the FIG., is that although mechanical disturbances can occur, the flexible suspension mounts result in dampened and/or reduced mechanical stress on component 103; at the same time, the connections between the component and the substrate are such that an unperturbed electrical output of the component 103 is still coupled from the component 103 to the substrate 105, that is, through and/or notwithstanding the presence of the flexible connection mounts.

It was earlier noted that the substrate 105 from FIG. 1 can be a die in some embodiments, a PCB in others, and potentially other types of structures. FIGS. 2A-2G are used to discuss some specific optional implementations; the structures depicted in these FIGS. are intended to be nonlimiting.

FIG. 2A shows one configuration 201 where an IC 203 is implemented as a two-die MEMS device and/or oscillator IC. As seen in this FIG., the IC 203 comprises a MEMS die and/or resonator 207 which is mounted adjacent a circuits die 209. The MEMS die and/or resonator 207 typically outputs some type of sensed signal which represents deflection and/or vibration of a MEMS body or resonator carried by the die. Note that while the FIG. illustrates solder bumps interconnecting the MEMS die and/or resonator with the circuits die, in fact, this depiction is symbolic, and serves as a proxy for any type of common electrical connection, including by way of nonlimiting example, an adhesive mount with one or more wirebond electrical connections. In this configuration 201, one or more flexible suspension mounts 213 are provided between the circuits die 209 and a second substrate 205, such that they are still operatively positioned between the MEMS die and/or resonator and the outside world. In this example, the MEMS die and/or resonator 207 can optionally be connected rigidly to the circuits die 209, while flexible suspension mounts 213 provide electrical interconnection between the IC 203 and the (second) substrate 205. The flexible suspension mounts inhibit/dampen transmission of mechanical disturbance from the substrate 205 to the IC 203 (including without limitation, the MEMS die or resonator 207). Note that FIG. 2A once again shows, i.e., via reference numeral 215, that the electrical connection(s) can optionally be provided for separate from the flexible connection mounts.

FIG. 2B illustrates an alternative configuration 221, in which like-numerals represent the same elements introduced relative to FIG. 2A. Whereas the configuration 201 seen in FIG. 2A featured one or more flexible suspension mounts 213 operatively coupling the (second) substrate and the circuits die 2009, in FIG. 2B, the flexible suspension mounts are seen to directly couple the MEMS die and/or resonator 207 and the circuits die 209. Note that the flexible suspension mounts 213 still operatively couple the MEMS die and/or circuits die 207 with the (second) substrate 205 (and the outside world). The effect of the flexible suspension mounts is to isolate the vibration-sensitive structure or device (i.e., in the MEMS die and/or resonator 207) from the rest of the system.

FIG. 2C presents yet another configuration 231, which is observed to be structurally similar to the configuration 221 seen in FIG. 2B. In FIG. 2C, however, the MEMS die and/or resonator is suspended (e.g., gravitationally) beneath the (second) substrate 205.

It should be appreciated at this point that there are a myriad of permutations and combinations of the various depicted structures, each of which is expressly contemplated by this disclosure. For example, it is expressly contemplated that the substrate 205 can mount the circuits die on top of it (i.e., as seen in FIG. 2A or 2B) and the MEMS die and/or resonator beneath it (i.e., as seen in FIG. 2C), or vice versa. It is also expressly contemplated that each of the depicted circuits die and MEMS die and/or resonator can be supported by separate flexible suspension mounts (e.g., one on top of second substrate 205, and one beneath). Also, the depicted configurations can also represent three (or more) respective dies; for example, either circuits die 209 or substrate 205 can be a complementary metal oxide semiconductor (“CMOS”) die, while another die can a different type/technology circuits die (e.g., a bipolar CMOS die, or “BiCMOS” die). Each of these configurations, and more, are viewed as within the scope of the techniques introduced by this disclosure; The various substrates and/or dies can be in any desired configuration, as long as at least the MEMS die and/or resonator 207 is operatively coupled to the outside world (e.g., including some type of supporting surface, such as substrate 205) via some type of flexible suspension mount.

FIG. 2D shows yet another configuration 241, in which a two-die system is configured with dies/structures being side-by-side atop the second substrate 205. In this case, the two-die system (e.g., a MEMS resonator die and CMOS circuits die, 207 and 209, respectively) are seen in a configuration where the MEMS resonator die is supported by one or more flexible suspension mounts directly on substrate 205, while the CMOS circuits die 209 is seen mounted directly to substrate 205 using a conventional (e.g., rigid) connection method, such as a solder bump mount. Per the discussion above, permutations of the embodiments thus far are also contemplated, e.g., with the CMOS circuits die and/or a BiCMOS die optionally also supported by flexible suspension mounts. As before, electrical interconnection to any given die can be provided by one or more flexible suspension mounts or by a separate structure which accommodates deflection/slight movement of the flexible suspension mount(s); the CMOS circuits die 209 can optionally also be coupled to the substrate, if desired, by a dedicated flexible suspension mount.

FIG. 2E shows still another configuration 261 which takes some of the disclosed principles a step further, e.g., a MEMS die and/or resonator 207 is seen mounted to a first substrate 206, while a circuits die 209 (e.g., CMOS circuits die) is seen as also mounted to this first substrate 206, each by a conventional mounting process (e.g., solder bumps, epoxy+wire bonds, etc.). In this case, the substrate 206 serves as an indirect proxy coupled to substrate 205 by one or more flexible suspension mounts 213, i.e., once again, the flexible suspension mounts are seen as “operatively coupling” the MEMS die and/or resonator with the outside world, even though the MEMS die is coupled to the first substrate 206 in a conventional manner. As before, electrical interconnection can be directly by the flexible suspension mount(s) in one embodiment, but it can also be separately provided in other implementations, as symbolically represented by dashed-line signal connection 215, and any given connection/support can be implemented as a flexible suspension mount.

FIG. 2F shows still another configuration 271, in which a die or other component (203, 207, 209) is mounted by a cavity wafer/substrate 205. Here, flexible suspension is at least partially provided by leaf springs 213/215, in a manner which provides for electrical connection as well. The FIG. shows alternate configurations (A and B) where a MEMS die and/or resonator 203 is either supported by or suspended by leaf springs 213/215. As implied by the alternative use of reference numerals 203, 205, and 207, flexibly-suspended components can include just the MEMS and/or resonator element, a circuits die such as introduced earlier, or both the MEMS and/or resonator element, in either configuration A or B, and within one or more of these elements within cavity 273. As also indicated by the FIG., part of the flexible suspension mount can also be provided by a material within the cavity, which is symbolically-represented by a liquid 275; such a material can optionally be a viscous material such as an oil, a gel, foam, or some other material, that is, provided that the combination of the leaf springs 213/215 and supporting material 275 combine to create the desired suspension properties. Note that leaf springs 213/215 and/or any electrical connections do not have to be either stiff and/or metallic in any embodiment, e.g., some designs use degenerately-doped silicon structures to act as electrodes, and still other embodiments use wire bonds, e.g., with a MEMS die and/or resonator being supported by a viscous material, such as a gel, foam or oil, as symbolically-represented in the FIG.

FIG. 2G shows a configuration 281 where a MEMS die and/or resonator is electrically coupled to a circuits die 207 and/or substrate 205 by wirebonds 283 and by an adhesive mount. In the depicted case, the combination of the adhesive mount and the wire bonds differs from conventional structures in that the provided suspension characteristics as described herein; again, this can be providing damping at a target frequency or within a range of target frequencies, for example, defined relative to an expected frequency of mechanical disturbance. As described elsewhere herein, this can be achieved, relative to conventional designs, by choosing support/mount materials, as well as an area of contact/force transmission to the MEMS die and/or resonator 207, in a manner that imparts desired spring and stiffness characteristics.

Note that FIGS. 2A-2G do not show encapsulation and/or lids, which are nevertheless present in many configurations. In a MEMS resonator-based system, the resonator die is typically itself hermetically sealed, e.g., with an internal MEMS body suspended in a vacuum, so as to impede exposure to elements which can affect the resonator's performance and longevity. It is also possible to have hermetic or other sealing provided at the package level and/or by other structures (e.g., with a lid and/or encapsulation not seen in these FIGS). In other types of sensors and/or devices, the configuration may differ; for example, a number of MEMS pressure and/or temperature sensor designs rely on the use of a membrane which is vented to an external atmosphere. Note that these designs are not exhaustive, e.g., as a nonlimiting example, it is possible to have a MEMS pressure sensor that is entirely encapsulated and for which change in resonant frequency is shifted as a function of pressure/materials stress.

With an introduction to some basic embodiments/configurations thus provided, this disclosure will now turn toward a more detailed discussion of some specifically contemplated structures and methods. It is again observed that all combinations and permutations of structures/techniques seen and/or discussed above, optionally combined with structures/techniques discussed below are specifically contemplated, even if not illustrated in a single, common dedicated figure of the Drawing.

FIG. 3A is a schematic diagram used in discussing impact of mechanical disturbance on an object, such as by way of example, a MEMS die or resonator component. Numeral 301 references the overall system, numeral 303 references a suspended object of mass “m” (e.g., such as a MEMS die and/or resonator component), and numeral 305 references a driving (support) object that is assumed to move in an undesired manner (e.g., a supporting surface or ‘substrate’ provided by a PCB, die or package lead frame); this driving object is therefore assumed to potentially transmit mechanical disturbance to the suspended mass “m.” Finally, numeral 307 corresponds to some type of flexible suspension or mount which couples the suspended object and the driving object. The flexible suspension or mount is designed to have both some stiffness as well as to provide a dampening effect, with the result that the suspended object will move according to the mathematical equation

$$m \ddot{x} + c \dot{x} + kx = c \dot{y} + ky ,$$

where ‘y’ denotes the vertical displacement of the driving object, ‘x’ denotes vertical displacement of the suspended object, ‘k’ denotes the spring constant of the flexible suspension, ‘c’ denotes the dampening coefficient of the suspension mount, a ‘single dot’ accent denotes a first derivative of a variable (e.g., x or y) and a ‘double dot’ accent denotes a second derivative of that variable (e.g., x or y). The driving object 305 is assumed to move as part of undesired mechanical disturbance (e.g., stress, vibration or impact).

Note that the displacement of each object may have a different amplitude (i.e., ‘swing’ or ‘distance’) and that, at least conceptually, may be characterized by different motion frequencies and/or phases of motion. The application of the depicted equation, in terms of design, depends on the nature of the expected mechanical disturbance. In one target application, problematic mechanical disturbances, as mentioned, can include vibrational or periodic disturbances cause by other electrical components, for example, mounted by a common substrate (e.g., PCB); in one specific example, vibrational at a frequency of 500 kHz is to be suppressed. Therefore, considering the equation above, the displacement ‘y’ of the driving object can be modeled as a sinusoidal force having periodicity of 500 kHz, and to obtain 31.86×-100.00× suppression of amplitude, the suspension frequency is designed to be within the range of 50 kHz-90 kHz (i.e., as suppression is then proportional to a square of the ratio of the two frequencies). In practice, such a suspension would be expected to deflect by a maximum of approximately 1-3 microns under a 30 k G, 0.12 millisecond half-sine wave shock event (e.g., which corresponds to MIL-STD-883 Method 2002.4 as a maximum test condition), where “G” refers to Newton's gravitational constant. In one embodiment, these parameters are employed specifically to provide a flexible suspension mount that is sufficiently stiff to avoid excess motion in response to this type of shock and, at the same time, sufficient compliant to dampen 500 kHz vibration; that is, given the expected frequency of mechanical disturbance of 500 kHz, and given a goal of having a dampening of between 31.86-100×, the suspension frequency is designed to be 5.56-10× less than this frequency, and the suspension mount is designed to accommodate displacement of, e.g., 1-3 micron such that a mechanical shock consistent with MIL-STD-883 Method 2002.4 will not cause undesired impact or collision of the suspended device with other components. Generally speaking, solution of the equation set forth above, for any anticipated mechanical disturbance is a straightforward solution to the second order differential equation depicted above, and is within the level of ordinary skill in the art.

FIG. 3B shows a graph 321 that illustrates some of the tradeoffs associated with design, once again, using the hypothetical example of a 500 kHz disturbance. More particularly, a first data plot 325 represents admittance, or transmission, of the 500 kHz disturbance as a function of suspension frequency and a second data plot 323 represents peak shock response as a function of suspension frequency; each axis corresponds to a logarithmic scale. Data plot 323 corresponds with the right y-axis while plot 325 corresponds to the left y-axis. The shock response function assumes a half-sin acceleration profile with 0.12 ms duration and 30,000 g peak value. The suspension mount is advantageously designed to minimize values of both data plots, e.g., to provide at least a 50% reduction in vibration amplitude and a maximum deflection under shock that is less than about 50 microns; these values correspond to a range 327, that is, extending between data points corresponding to these two values. In terms of specific suspension frequency, this range 327 corresponds to a suspension frequency of about 14 kHz through about 290 kHz, once again assuming a 500 kHz mechanical disturbance; these values also equate to roughly between 2.8% and 58% of the modeled disturbance frequency. If it is desired to obtain even greater suppression, e.g., with at attenuation of a least about 90% and a peak motion response of less than about ten microns (assuming the test condition specified), then the suspension frequency is designed to fall in the range of 50 kHz to 150 kHz; this corresponds to a suspension frequency that is within the range of about 10%-30% of modeled disturbance frequency. This is illustrated by range 329 in FIG. 3B. It is generally anticipated that most integrated circuit coupling implementations which make use of a flexible suspension mount of the type described, e.g., in connection with this embodiment, will conform to one or both of these ranges, although there may be some implementations which do not.

FIGS. 4A-4C are used to discuss one specific embodiment 401 of a flexible suspension mount. In the depicted configuration, a first integrated circuit/substrate 403 features relatively stiff metal electrical leads 407 are individually structured to effectively serve as springs while also providing a flexible suspension. In the depicted embodiment, a deposition process has been used which encases the leads 407 within a protective material 405, and in a manner where solder bumps can also still be received in contact with the electrical contacts for these leads for electrical assembly purposes, that is, notwithstanding the presence of the protective material. Reference numeral 411. denotes that the flexible suspension and the protective material 405 function together and provide robustness to mechanical disturbance prior to integration, packaging, product assembly, and/or distribution.

As depicted in FIG. 4A, at some point, the first IC/substrate is flipped, per numeral 413, and connected to a second IC or substrate 415, with the protective material thereafter being removed (e.g., etched, deactivated, or otherwise released) so as to enable the depicted electrical leads 407 to serve double-duty as a flexible suspension mount. For example, numeral 416 denotes that the protective material has been removed, such that the IC/“first” substrate is electrically engaged with the second IC/substrate 415 by solder bumps, and such that the electrical leads function as metallic springs. This is conceptually represented in the FIG. by depicted distances 417 (h) and 419 (l), i.e., the metal leads are structured to permitting shock response consistent with a lever arm length (corresponding at least i part to depicted quantities l height h). When mechanical disturbance is encountered by the second IC/substrate, the lever arm length and height permit motion of the second IC/substrate to be absorbed and/or transduced according to deflection of the metal leads, resulting in reduced force transmission to the first IC/substrate 403.

In one specifically contemplated embodiment, the first IC/substrate can be a MEMS resonator die or an oscillator IC (e.g., having a MEMS resonator die), and the depicted four-pin electrical interface provides for transfer of a drive signal, an output oscillation signal, a temperature signal, and a voltage reference (e.g., ground or another reference). A smaller or greater number of pins can be used, with associated tradeoffs in the flexible suspension structure, and the pins can be used to transmit different signals that those indicated. In one contemplated embodiment, one or more of these pins can receive signals from externally, e.g., configuration signals and/or programming, though this will depend on the specific design of the first IC/substrate 403.

FIG. 4B shows a perspective view 421 of a more detailed embodiment based on this design. More specifically, numeral 423 identifies a first IC/substrate having a four-pin interface after it has been flip-chip mounted to a second IC/substrate 425. Four pins respectively correspond to letters A-D which appear in some of the FIG.'s numerical references. Each electrical lead corresponding to these pins generally has three parts, including a first stud which electrically interfaces to the first IC/substrate 423, a second stud which provides for a contact that will receive solder bumps (i.e., which will mechanically and electrically engage the second IC substrate 425), and a serpentine metal connection for each pin which interconnects the two corresponding lugs, and thereby electrically and mechanically interfaces the two ICs/substrates. These three parts are defined in three or more layers (429, 431, 433), which together will define the flexible suspension mount and protective material, which are collectively represented here as a layer sandwich 427. In one embodiment, the leads are made out of a conductive material such as copper, but other conductive materials including, without limitation, other conductive metals can also be used. The serpentine structure is seen in this FIG. to be generally configured to have a “V” or “chevron” shape which generally implements a lever arm length and a displacement height, as was introduced relative to FIG. 4A; in the depicted design, the use of this “V” or “chevron” shape, the fact that there are four pins, and the fact that the studs in each pin set are laterally offset from one another, all contribute to provide stability to a wide range of mechanical forces which might otherwise affect the same substrate (e.g., resistance to rotational displacement around each of three rotational axes, linear displacements along each of three cartesian axes, or any combination of these things). Naturally, other configurations of the leads can be used, depending on conductive material used, number of pins in an electrical interface, first die/substrate mass, and a variety of other factors; the selection of appropriate materials, routing and dimensions represent implementation details that ca be selected depending on application by a competent designer having ordinary skill. In the FIG., numeral 429 denote a layer which is “closest to” the first die/IC, and which is used to define the first stud for each pin (which is correspondingly identified using numerals 429A-D). Numeral 431 denotes an intermediate layer, generally used to define the serpentine metal trace for each lead, which then connects the associated stud pair—these leads are correspondingly identified using reference numerals 431A-D. Finally, numeral 433 denotes a layer which is “closest to” the second IC/substrate, and which is used to define the second studs for each pin (which are correspondingly identified using reference numerals 433A-D).

FIG. 4C provides additional detail regarding this four pin interface. In particular, a left-hand side 441 of the FIG. represents a redistribution layer (“RDL”) image, showing the studs and serpentine lead connection for each pin, and the “V” or “chevron” structure just discussed. A right-hand side of the FIG. shows the dimensioning of one of the leads, e.g., in order to provide a lever arm that will partially define the appropriate spring and/or dampening parameters. In this regard, the second of four pins (i.e., corresponding to the letter “B”) is seen in enhanced detail, including first and second stud configurations (429B and 433B) respectively, and the metallic lead structure which interconnects these two (431B). Numerals 419 and 431 in the FIG. respectively show length and width dimensions associated with a lever arm which permits each metallic lead to function as a spring, while numeral 443 shows an elbow in the configuration of the metallic lead which, once again, in combination with the three other pins of the electrical interface, provide robustness to a wide variety of rotational and/or linear-displacement mechanical disturbances.

FIGS. 5A-5L are used to discuss one manufacturing method which can be used to build a flexible suspension mount of the type just described, e.g., with two dies/substrates that are mounted together with a flexible suspension mount therebetween. Note that the structures of FIGS. 1-4C can optionally be manufactured using other methods, and conversely, that the method discussed with respect to FIGS. 5A-5L can be used to make other devices besides those seen in FIGS. 1-4C. It should also be noted again that the shading in FIGS. 5A-5L is changed from FIG.-to-FIG. to emphasize structures and/or steps being discussed in relation to the individual FIG.

More specifically, FIG. 5A shows a first die or substrate 501 having two different sets of bond pads 503 and 505; the bond pads are seen as shaded in this FIG. The first die or substrate in one embodiment is an already-built CMOS circuit die, for example, used to support operation of a MEMS resonator (e.g., a “dual-MEMS” die having two different MEMS resonators). The first die or substrate in a different embodiment can be an already-built MEMS die (e.g., a resonator die) or another type of substrate.

As seen in FIG. 5B, two layers including a protective layer 507 for the bond pads (seen in dark shading) and a sacrificial layer 509 (seen in light shading) are then deposited atop this assembly, using masking of bond pads 503/505, such that they remain exposed following this process. These layers are effectively used to define templates for the flexible suspension mount in this embodiment, e.g., studs 429A-D and metal leads 431A-D, which were discussed above in connection with FIGS. 4A-4C, as will be seen in the ensuing FIGS.

FIG. 5C shows ensuing deposition of a plating seed layer 511 (highlighted with dark shading) and a mask layer 513. Following these steps, conductors are then formed using the mask layer, as seen by the presence of shaded structures in FIG. 5D; for example, in this embodiment, a copper plating step is performed to define studs/metal leads (referenced by numerals 516 and 517), as well as large standoffs 515.

Another mask layer 519 is then deposited, as best seen in FIG. 5E; this mask layer 519 is then used for deposition of a second set of connection studs atop structures 517. In FIG. 5E, the deposited conductors have been left lightly shaded, so that it can be better seen exactly where these studs will be formed).

FIG. 5F shows ensuing formation of the studs 520; an under-bump metallization layer 521 is then added to cover exposed metals corresponding to structures 515 and 517.

Following these steps, another mask layer 523 is then deposited atop these structures, with the mask layer defining apertures for the large standoffs 515. Large solder bumps 525 are then added over this mask structure, as best seen in FIG. 5G. Note that the combination of large standoffs and large solder bumps 525 and 515 will be used in this embodiment to define a stack, that is, with the flexible suspension mount lying in between these large standoffs and large solder bumps 525 and 515, i.e., within a central region designated by a bracket 526 seen in the FIG. This configuration is not required for all embodiments.

As best seen by comparing FIG. 5H with FIG. 5G, the mask layer 523 is then stripped, exposing studs 520; a set of conductive adhesive bumps 527 is deposited, in a manner aligned to the second studs 520. In another embodiment, the bumps 527 can be solder and can be formed before, or concurrently with, the large solder bumps 525. In yet another embodiment the conductive adhesive or solder bumps are deposited on a secondary die, 529 in FIG. 5I, in alignment with the studs 520. In this case adhesion to the studs 520 is made during the assembly step illustrated in FIG. 5I.

Note that in the depicted configuration, it is then possible to transport the depicted assembly, e.g., with a flexible suspension structure still being protectively encased and not fully released; if appropriate, an oxide resistant capping layer can optionally be used to prevent oxidation and/or corruption of exposed materials. Note that in some embodiments, manufacture simply is continued to the next step without break (e.g., and without breaking a vacuum used as part of the manufacturing process).

When it is desired to perform further assembly, as seen in FIG. 5I, a second die/substrate is then mounted atop the conductive adhesive bumps, such that the second die/substrate 529 is electrically connected to the first die, but at the same time, is supported above the first die, as indicated by the presence of voids 533. Optionally, the first die/substrate is also subjected to a wafer thinning process (e.g., if the first die/substrate is a raw wafer, e.g., CMOS or other circuits can then be added to a machined, bottom surface). As was introduced above, in one embodiment, the second die/substrate 529 can be a MEMS resonator die and the first die/substrate can be circuits die, e.g., to provide CMOS and/or BiCMOS sense and sustaining circuitry for the resonator; these FIGS., however, should be understood to also explicitly designate the inverse configuration, that is, where the first die/substrate is the MEMS resonator die (or other resonator or MEMS structure of some type) and the second die/substrate corresponds is a circuits die.

As illustrated in FIG. 5J, the sacrificial layers are then removed from regions 535, to fully expose the flexible suspension mount(s). The second die/substrate is thus seen to be supported by structures 517 by 1-3 microns above the first die/substrate 501. As referenced earlier, structures 517 are advantageously dimensioned so as to provide specifically engineered suspension characteristics (e.g., frequency, spring constant, dampening coefficients, etc.). of the type discussed above; once again, optionally, the suspension frequency can optionally be between 2% and 25% of a target mechanical disturbance frequency (i.e., optionally, a standardized test signal, such at the 500 kHz disturbance referenced above), and preferably between about 10% to 18% of the target mechanical disturbance frequency.

As seen in FIG. 5K, the entire assembly is then flipped and mounted to another substrate 533 (e.g., a PCB, an integrated circuit lead frame, another die, etc.). This other substrate 533 has bond pads 537 that will receive the large solder bumps and provided for electrical interconnection between substrate 533 and first die/substrate 501; note that the second die/substrate 529 (e.g., a MEMS resonator die in one embodiment) remains suspended within a central cavity 539 seen in the FIG.

Finally, in an optional process depicted in FIG. 5L, the second die 529 is then sealed to the first die 501 using an edge bead epoxy 541, to protect the exposed suspension. The latter “dual MEMS die” is not illustrated in FIG. 5A, and it should be noted that the depicted techniques are not restricted to a use of a dual-MEMS die. Note that this edge bead epoxy is not required for all embodiments, i.e., some embodiments discussed below will use a protective layer that is selectively released at a later point in time (e.g., in place of the edge-bead epoxy seen in this FIG).

FIGS. 6A-12B are used to discuss some further structures and strategies. It is emphasized that the structures and strategies described in these FIGS. are optionally combined with a flexible suspension mount, as described above, and conversely, the flexible suspension mounts described earlier are optionally combined with the mounting strategies discussed in FIGS. 6A-12B. This is to say, neither a flexible suspension mount as described above, or a suspension frequency meeting specific criteria discussed above, are required for any embodiment. Conversely, the use of an expanding material and/or temporary structures which change suspension characteristics and/or calibration processes, described for embodiments discussed below, may also each be practiced in isolation, or in combination with the other features disclosed herein.

More particularly, FIGS. 6A-6E are used to illustrate use of a shape-morphing attach material which initially attaches a resonator and/or MEMS die in a relatively stable format (e.g., in stiff adherence, to facilitate wire bond or other processes), and which is then activated or released, so as to change suspension properties and provide a more flexible suspension. The embodiments seen in these FIGS. are similar to those discussed above, in that they ultimately provide a flexible suspension mount that reduces transmission of mechanical stresses between a first die/substrate and a second/die substrate. This flexible suspension mount is based in some embodiments on a foaming epoxy and/or other material on a foaming or expanding material, generally designated by numeral 607 in FIGS. 6A-6D. The material 607 can be designed to expand as a function of age (e.g., after a period of time), upon a trigger, such as upon application of a temperature increase, electrical stimuli, UV irradiation, exposure to moisture or another chemical, upon removal, disconnection or etch, or as a consequence of some other action. The trigger and/or release can be performed in some embodiments at a predetermined epoch, for example, following IC mounting, packaging, after installation of a package in a consumer product, or at another defined event. Note that an initially-rigid die connecting material can facilitate assembly, e.g., electrical interconnection effectuated such as by wire-bonding a die (e.g., MEMS die) to its support (e.g., CMOS die); the foaming and/or compliance in one embodiment is selectively triggered after electrical interconnection and mechanical mounting is complete, thereby minimizing effects from unintended stresses imposed as part of the assembly, packaging and/or other installation processes.

FIG. 6A is a side view of an embodiment 601 featuring a die 603 attached to a supporting substrate 605; as before, the supporting substrate can be a PCB, another die, a semiconductor wafer, a portion of a lead frame (e.g., of an IC package), or some other conventional structure that supports a die. The FIG. shows a flexible material 607 used to support the die 603 on the substrate, wherein the flexible material is not chip scale, meaning that in this embodiment, there is at least some area of overlap 608 between the die 603 and the substrate 605 where the flexible material 607 is not present. In this embodiment, the flexible material will be expanded at some point, to provide for a flexible suspension mount for the die 603, but here in FIG. 6A, the material 607 is seen in a compressed state, such that it has a height “h1” and provides a relatively rigid interface between the die 603 and the substrate 605; this rigidity is represented in the FIG. by the depicted spring constant “k1” and dampening coefficient “c1.” The material 607 is seen in this embodiment to be an insulator, i.e., electrical connections are provided by an independent interconnection structures in this FIG.; the presence of wirebonds 609 represents these connections, although note that this depiction is symbolic and nonlimiting, e.g., in one embodiment, the compressed state of material 607, and the relatively greater rigidity of this connection facilitates wirebond attachment, but other means of electrical connection between die and substrate can also be used, including without limitation, via a conductive tape. Note that, advantageously, when wirebonds are attached, some amount of slack is provided to accommodate the expansion of material 607, which is described in the following paragraphs.

FIG. 6B shows this same embodiment 601, but after the material 607 has been activated and/or released, such that it expands to a different height, as represented by expansion arrows 611, and expressed height “h2;” similarly, as represented in the FIG., in this embodiment, the density of material 607 changes, such in its expanded state, the material 607 provides a much more resilient/flexible support structure, which is represented by the presence of a different spring constant “k2” and damping coefficient “c2.” The slack mentioned in the previous paragraph serves the purpose of permitting this expansion without constraint. As noted earlier, in one embodiment, the material 607 can be a foaming adhesive that naturally decompresses over time, that is triggered by an activating event, or that is released in some other manner, for example, etch of a release material. The foaming adhesive can be selected and/or chemically structured such that, when it is fully expanded, it provides spring force and/or dampening factors suited to the specific design. For example, in one implementation, the foaming agent can be selected and/or designed such that it effectuates a flexible suspension frequency as discussed above in connection with FIG. 3B, i.e., to fall within one of the ranges depicted in that FIG. Note that it is within the ordinary level of skill of one familiar with polymer chemistry to select and/or design a suitable material to achieve these ends.

FIG. 6C illustrates a variant 621 where a foaming material is used, as discussed above, but in connection with a MEMS die and/or resonator 613 that uses a flexible suspension mount (e.g., with spring-like metallic leads, as described earlier). In this case, the foaming material is selected to effectively prestress the mount so as to have desired suspension characteristics (i.e., desired spring constant, suspension frequency, dampening coefficients and/or other characteristics). As will be discussed further below, in implementations where circuitry provides for some type of temperature compensation, the foaming/expanding agent can be selectively actuated in situ, with characterization, calibration and/or compensation being thereafter measured, i.e., after the completion of expansion and any associated cure period, with temperature compensation data only then being identified and programmed. Such a process helps mitigate the possibility of manufacturing-induced performance shift, and provides for development of more accurate temperature compensation data (i.e., as such is generated/measured/programmed after the occurrence of manufacturing-related stress.

FIG. 6D shows yet another variant 631 where a foaming material is used, as discussed above, but where the foaming material prestresses a flexible suspension mount from an opposing side of the MEMS die and/or resonator 613, that is, by expanding in a manner that imposes a compressive force on the flexible suspension mount, caused by expansion of material 607 at a location in between a lid 615 and a top surface of the MEMS die and/or resonator 613.

FIG. 6E shows still another configuration 641; this configuration is similar to the one seen in FIG. 6D, except here, the MEMS die and/or resonator 613 is seen as supported laterally, by leaf springs 627, which also provide for electrical interconnection. This configuration generally conforms to configuration “B” which was introduced earlier in connection with FIG. 2F. In this case, optionally, a cavity wafer 625 is used to house the MEMS die and/or resonator 613, and the cavity can optionally include a flexible material such as a foam, gel, adhesive or oil, as represented by numeral 629. In this case, as the material 607 expands, it prestresses leaf springs 627 and, to the extent necessary, displaces the flexible material 629.

It was noted earlier that, in some embodiments, the area of interface between a mounted die and underlying substrate is also advantageously reduced, as a means of limiting mechanical perturbation. FIGS. 7A-7B are used to discuss considerations pertinent to this reduction of interface surface area.

Note that some embodiments described earlier can be structured so as to inherently minimize die interface surface area; that is to say, the use of a four-pin spring interface that performs double-duty as both suspension and electrical connection structures, provide for a reduced contact area and a connection robust to deformation in a number of different degrees of freedom (e.g., 3 translational and 3 rotational).

FIG. 7A provides a graph 701 that plots design data 703 useful to a designer in selecting constraints for an area of mechanical interface between die and substrate. More specifically, assuming a normative ratio of connected area to die area of “one” (e.g., the die is mounted on one side only by an adhesive), it is seen that the average first principle (tensile) stress drops to about half as the area of interconnection is reduced to 40% of die area, and that further gains are achieved as the area of mechanical interconnection is reduced further.

Referring briefly to FIG. 7B, which shows a configuration 711 having a first die/substrate 713, supporting substrate 715, and an area of interconnection 717 (e.g., provided by a flexible suspension mechanism), it is seen that reducing each dimension of mechanical interface to approximately 63% of die width/length, produces an interface area matching this 40% criteria. As should be appreciated, while a square area of interface is depicted in this FIG., it should be observed that rectangular interface areas and other configurations can also be used; some interface structure patterns associated with these configurations will be further discussed below in connection with FIGS. 10A-10F.

FIGS. 8A-8E and 9B-9C show various embodiments which also use an expanding material, as described above, but which also specifically limit an area of mechanical interface. More specifically, FIGS. 8A-8E are used to illustrate use of an adhesive tape that includes both an expanding material as well as a temporary adhesive and/or release structure, while FIGS. 9A-9E more generally show configuration where suspension characteristics are changed by the removal or disengagement of material and/or structures.

An embodiment 801 seen in FIG. 8A features a die 803 which has an adhesive tape 804 attached to its underside. The adhesive tape 804 will be used to adhere the die to a substrate 805, and comprises, in a first layer 806, a pattern of one or more expanding structures 807 and one or more temporary adhesive and/or release structures 809. Note that, in this embodiment, there are portions of the layer which define voids 810, though this is not required for all embodiments. A second layer 811 of the adhesive tape comprises a permanent adhesive; in assembly, the die 803 is mounted to the substrate 805 in the manner indicated by directional arrows 813.

As seen in FIG. 8B, following adherence of the die 803 to the underlying substrate 805, electrical connection is effectuated, as once again depicted symbolically using wirebonds 815. Note that, at this time, the adhesive tape provides for a relatively rigid mounting, and is characterized by spring constant k1 and damping factor c1. This relatively rigid mounting facilitates electrical connection, and subject to completion of any remaining manufacturing steps (e.g., which can depend on design and/or implementation), the depicted embodiment 801 is advantageously kept in this state until it is desired to activate/release the release structures 809.

As depicted in FIG. 8C, at some point, the release structure(s) is(are) engaged or triggered, which causes the flexible material 807 to expand, as indicated by arrows 817. This is to say, FIG. 8C no longer shows the presence of release structures 809, which in this embodiment are etched or dissolved. Note that removal of the release material is not required for all embodiments, e.g., depending on design, the release structures can remain and can be activated by UV light, heat, chemicals, age (e.g., time) and/or other mechanisms as referenced earlier. In an assembly process that is expected to be completed within a predetermined maximum period of time, it is also possible to use a time-release structure which automatically releases, e.g., “1 week after assembly.” As indicated by text notation in the FIG., once the material 807 has expanded, the depicted suspension is now characterized by a second spring constant k2 and second dampening coefficient c2. Once again, although not required for this embodiment, in some implementations, a designer may choose to use those design considerations described earlier, e.g., to provide a suspension frequency corresponding to one of the ranges seen in FIG. 3B and/or otherwise as a function of an expected mechanical disturbance or test condition. Note that, as depicted, the permanent adhesive layer 811 remains as a permanent part of the flexible suspension mount.

FIG. 8D shows another embodiment, generally referenced by numeral 821; this FIG. shows that an adhesive tape can be deployed in a reverse configuration, that is, with a flexible material that still expands (i.e., per expansion arrows 823), but this time with a permanent adhesive layer 825 directly abutting die 803.

FIG. 8E shows yet another embodiment 831, which depicts that in some embodiments, the release structures 809 can remain attached to the permanent adhesive layer 811 or the die 803 or the substrate 805; that is, while only one of these configurations is depicted in the FIG., the FIG. should be understood as proxying a configuration where the release structure simply releases one of its sides, and remains in the assembly adhered to either the permanent adhesive layer 811 or the die 803 (as was seen in FIG. 8A).

It is of course possible to have any number of layers, arranged as any desired combination or permutation of the structures described above, or elsewhere herein; as a nonlimiting example, designs are contemplated where a permanent adhesive layer corresponding to layer 811 in FIG. 8B is used also with a permanent adhesive layer 825 in FIG. 8D (e.g., with an expanding material 807 deployed between these layers). Many combinations and permutations are possible, and are explicitly contemplated herein, notwithstanding that each such possible implementation is not shown by a single dedicated figure of the Drawing.

FIG. 9A shows a configuration 901 which does not rely on an adhesive tape, but rather, uses structures which have been deposited using semiconductor deposition processes and/or rely on use of a die attach film.

In FIG. 9A, a die 903 is once again seen as connected to a supporting substrate 905 using an material 907, one or more temporary and/or release structures 909, and separated electrical interconnections, such as depicted wirebonds 909. Such an embodiment can for example be constructed using deposition processes to deposit structures 907 and 909, with a heat process used to attach die 903 to these structures (or the die can be grown/built-up over these structures); alternatively, a die attach process (discussed below) can also be used. The configuration 901 is seen to be by spring constant k1 and dampening coefficient c1. Once again, as seen in the FIG., wirebonds 915 are used to provide for electrical interconnection, although once again, this depiction should be understood to encompass other types of electrical interconnections as well.

FIG. 9B shows this same embodiment 901, but after etch (e.g., chemical etch) or other removal of temporary structures 909, which permits the flexible material to expand, per numeral 917, and to settle into an expanded state, in which it provides for a desired degree of flexible suspension (as denoted by the presence of spring constant k2 and dampening coefficient c2).

As was the case with the embodiment of FIG. 8C, it is of course possible to have release structures 909 which remain in the completed assembly, once again, being adhered to either the die 903 or the supporting substrate 905 (as was seen in FIG. 9A). Such a configuration is seen in FIG. 9C, where these structures are seen retained in contact with substrate 905 (though it is equivalently possible to have these structures remain in contact with the die 903, as was seen in FIG. 9A prior to detachment). In the embodiment 921 of FIG. 9C, the release of structures can once again be effectuated by UV light, heat, electrical or chemical means.

FIG. 9D shows yet another embodiment 931; in this case, the material layer 907 is not an expanding material, but the nature of the temporary attachment is such that the etch or removal of structures 909 (seen in FIG. 9A) causes the suspension to change its characteristics, i.e., from providing a relatively rigid support to providing a flexible suspension mount as described elsewhere herein. As depicted in the FIG., removal of structures and/or material causes a change in suspension characteristics from k1,c1 to k2,c2.

FIG. 9E shows yet another embodiment 941 where die is attached to a substrate (not shown) using a die attach film 945. A wafer 943 is positioned atop the die attach film 945, which comprises an adherence layer 947 and a-adhesive backing 941. The backing is seen as supported by a chuck 951, with a heat and/or pressure being applied, per arrow 953, to activate the adhesive layer 947 and to fuse that layer to the bottom of the wafer 943. The structure may then be diced, e.g., as indicated by separation lines 955, with each individual die assembly 957 being lifted and positioned for mounting on a substrate (again, not shown in this FIG.). At this point, each die assembly comprises the die itself 959 (e.g., CMOS or MEMS/resonator) and a part 961 of the adherence layer, separated from backing 949 as indicated by a directional arrow 963. Depending on materials, used, the die assembly 957 can then be bonded to a corresponding substrate (e.g., using a heat, UV, or other process to reactivate the part 961 of the adherence layer to provide a permanent mounting). Optionally, the adherence layer 947 can comprise an expanding material as was indicated by the FIGS. discussed above, a pattern of temporary adhesives (which may or may not be completely removed by the activation process) and permanent adhesives (which may or may not expand on activation), as illustrated in in FIGS. 9A to 9D, or it can provide another type of flexible suspension. In one optional embodiment, the adherence layer comprises an adhesive, or several patterned adhesives, such that after dicing (as seen in FIG. 9E), the pattern permits bonding to a corresponding substrate upon contact and/or through additional application of heat and/or pressure.

It was earlier mentioned in connection with FIGS. 8A-9E that many different patterns can be utilized for configuration of temporary and permanent structures; FIGS. 10A-10F are used to provide nonlimiting examples of patterns that can be used. In these FIGS., numeral 1001 denotes an area of die interface with a supporting structure, while shaded structures represent one of the permanent (expanding or nonexpanding) structures or the temporary structures, with light-colored shading being used to denote the absence of these structures. For example, FIG. 10A shows a square structure 1003, FIG. 10B shows a circular structure 1005, FIG. 10C shows use of plural structures 1007, FIG. 10D shows use of a peripheral wall 1011, FIG. 10E shows use of a repeating pattern, configured as a mesh 1015, and FIG. 10F shows use of reciprocal structures 1017; it is possible to have any combination of shapes, for example, use of a circular-cross section expanding structure 1005 seen in FIG. 10B together with a square-shaped peripheral release structure 1011 seen in FIG. 10D, or vice-versa. As implied by this discussion, many possible patterns and/or configurations will occur to those having ordinary skill in the art, and these illustrated structures are once again provided simply as nonlimiting examples. Note that the depicted patterns can represent either expanding or nonexpanding materials, adhesive or pressure/heat activated-structures, die attach/die patterns, or other structures of the type discussed above.

To facilitate discussion of some of the novel techniques provided by this disclosure, some of the embodiments discussed above did not discuss packaging and/or encapsulation options. Not all implementations require encapsulation and/or additional encapsulation. For example, in the case where a MEMS die and/or resonator contains, within its body, a hermetically-sealed structure, no additional encapsulation may be necessary. Techniques are known, for example, for fabricating dies using two or more bonded substrate and/or using a built in release layer, which is then etched through vents, to free a deflecting or vibrating body, with the vents thereafter being plugged or sealed. In other configurations, e.g., a MEMS pressure sensor, encapsulation is typically partial, for example, leaving a flexible membrane exposed such that pressure differential can be sensed. For structures such as these, that is, where a die comprises all necessarily encapsulation, these structures are already represented by the FIGs. seen above (i.e., the encapsulation can be an unseen part of the depicted dies).

In many embodiments, however, it may be desired to provide additional encapsulation or protection to protect a flexible suspension that is external to a mounted die from contact (e.g., from being bumped), exposure to an external temperature or atmosphere, or for other purposes. FIGS. 11A-E are to discuss some of these options.

FIG. 11A shows an embodiment 1101 where a die 1103, mounted to a substrate 1105, is sealed using a glob 1109 (e.g., a gel, foam, polymer or other structure). The encapsulation can be hermetic, but need not be in all embodiments. As depicted in the FIG., the die can be electrically interconnected by a solder bump mount 1107, which interfaces with a flexible suspension 1109, built according to various embodiments described above. Note that, while the FIG. graphically depicts the same flexible suspension mount structures that were introduced by FIGS. 4A-4C, it is also possible to use an expanding or other flexible suspension structure, as described elsewhere herein. As indicated in the FIG., the flexible suspension mount advantageously provides a suspension frequency that achieves objectives specified herein, that is, resulting in reduced transmission of mechanical disturbances to the die 1103; this is represented (once again) by the depicted presence of spring constant k2 and dampening coefficient c2 in this FIG. The glob 1109 protects the die from direct contact with other structures, while the flexible suspension mount protects the die from mechanical disturbances transmitted through substrate 1105 and/or via the mounting of that substrate, represented by symbolic presence of large solder bumps 1111.

FIG. 11B shows another embodiment 1115, which is similar to the embodiment seen in FIG. 11A. That is, here also, a glob 1109 is used to protect die 1103. In this case however, the die and the glob 1109 are disposed in between the large solder bumps 1111, which serves as standoffs, i.e., at a height 1116 above a supporting structure (not shown); this height is greater than, and provides overhead for a distance/height below the substrate 1105 which accommodates the die 1103, the suspension mount and the glob 1109.

FIG. 11C shows yet another embodiment 1121, in which where die 1103 and its supporting substrate 1105 are together mounted/packaged within a cavity device 1123. In this case, the cavity is seen enclosed by a lid 1125, which establishes a protective chamber 1126 in which the die 1103 is sealed. As with prior embodiments, wire bonds can be used to electrically connect the supporting substrate 1105 to the cavity device 1123, with internal pillars 1129 used to electrically route signals to a package exterior; for example, these pillars 1129 are seen as connecting to solder bumps 1131, which are used in this embodiment to mount the package and electrically interface the package with the outside world. In the depicted embodiment, an adhesive 1128 is used to mechanically support substrate 1105, although any mechanism may be used for this mechanical support, including a flexible suspension, oil, cement, etc.

FIG. 11D shows another embodiment 1131 which is similar to the one seen in FIG. 11C, but here, the substrate 1105 is also used as a lid, with die 1103 being suspended from that lid using a flexible suspension mount. Once again, the spring-like four-pin structure introduced in FIGS. 4A-4C is graphically depicted in this FIG., but it should be understood that this graphic is a symbolic proxy for any of the structures/embodiments described herein. In this particular illustration, a device 1133 once again provides a cavity in which the die 1103 is mounted, with pillars or vias 1135 being used to establish electrical interface between die 1105 and an electrical mounting structure (represented by solder bumps 1137).

FIG. 11E shows another embodiment of a packaged assembly 1141 (e.g., an IC). In this case, once again, a die 1103 is seen supported by a flexible suspension mount relative to a substrate 1105, but here, the substrate is directly mounted to a lead frame 1142. In this embodiment, the substrate 1105 is seen as also being supported by an adhesive layer 1143, with a lateral seal 1145, and with wire bonds 1147 being used to establish electrical connection to the lead frame. Note, however, that any support and/or electrical connection mechanism can be used. As depicted in the FIG., the lead frame routes electrical interconnection to supporting pins (not shown) for the packaged structure, via standoffs 1151; the entire assembly 1141 is encased in a plastic 1149. The plastic in this configuration is rigid, and provides an internal chamber 1153 in which the die 1103 subsists and is allowed to operate.

The various structures described above, particularly those with a shape morphing die attach, or which otherwise utilize some type of activated layer or release layer, provide for a construction that is relatively robust to mechanical perturbation during manufacture, assembly and potentially distribution. However, changing suspension or mount following manufacture (and after characterization) can also potentially unacceptably shift device performance. FIGS. 12A-12B are used to discuss additional embodiments that help mitigate this possibility by providing for device characterization after manufacture, and in some cases, after assembly and/or distribution.

In one specifically contemplated implementation, the techniques described herein are applied to the manufacture of a temperature-controlled oscillator (or “TCXO”). A resonator is used as a first device to generate a reference oscillation signal. In some embodiments, a quartz crystal can be used for the resonator, but in other embodiments, a MEMS silicon resonator is used which has a doped crystalline body which deflects or vibrates on a very even basis under the application of drive impetus. As noted earlier, in some embodiments, the resonator can include a piezoelectric layer. A second device is used primarily as a temperature sensor; in some implementations this can be a thermistor, while in other embodiments, a second resonator having strong, linearly varying (i.e., first order) TCF is used as a temperature sensor, with the difference between resonant frequency of the two resonators used as an index to temperature. The identified temperature, in digital form, is then used to look up correction factors which are applied to an output of the first resonator (i.e., a ‘temperature-flat’ resonator) and used to correct minor temperature-dependent variation, so as to produce a temperature invariant output signal. Temperature correction of this general type can be used for all types of MEMS devices in order to provide an output which will not vary according to temperature. Generally speaking, to perform temperature correction of this type in these types of devices, as each individual device is manufactured, it is calibrated by probing the device under different temperatures to learn how output varies according to temperature, with correction factors used to correct this variance then being programmed into circuitry for the device for use in a manner that will be used to negate temperature dependent variation. Indeed, absent the novel techniques provided by this disclosure, ‘creep’ and other forms of disturbance and thereby render these learned correction factors obsolete or inaccurate. In some embodiments, the depicted structures themselves correct temperature dependent variation (i.e., using onboard circuitry), while in others, temperature correction information is provided as an output.

In some embodiments, on-board structures are provided as part of a manufactured device and/or its support circuitry to perform characterization at a selected time and thereby help mitigate against creep and/or performance shift. Generally speaking, these onboard structures provide for one or more of the following: (1) a die assembly of some type has a flexible suspension mount of one of the types indicated herein, or a shape morphing die attach of the one of the types indicated herein; (2) the die assembly has a built-in heating element of some type for thermal characterization; (3) the die assembly has a temperature sensor that provides an output used to indicate current temperature of the assembly (or a structure within, for example, a resonator or other MEMS structure; (4) the device has memory to store temperature correction coefficients; and (5) one or more of these structures are used in combination to, in situ, e.g., in the presence of a flexible suspension (and/or after shape change for example caused by an expanding material) provides for characterization only after the suspension has been deployed in its final, i.e., normal, operating state. For example, an integrated circuit having these elements in combination can be manufactured and packaged as part of an integrated circuit assembly; one or more release and/or shape-changing materials are then activated, such a flexible suspension is then deployed, e.g., at a late stage in manufacturing or assembly. Finally, a built-in heating element and temperature sensor are cycled through a calibration operation, to learn temperature sensitivities and to program correction factors into the device, for use in later, normal, run-time operation of the device. In one embodiment, on-board processing circuitry uses these programmed correction factors to create a temperature-invariant output. In another embodiment, as noted, the programmed correction factors are output for use by a downstream device (e.g., a central processing unit or “CPU”), which performs downstream correction of temperature-dependent variation; as an example, the four-pin structure introduced by FIGS. 4A-4C can feature one pin used for drive, one pin used for output of a sensed characteristic (e.g., MEMS resonator frequency), one pin used for output of a temperature signal (i.e., digital values representing current temperature) and one pin used for output of temperature correction factors (e.g., polynomial coefficients for use by a downstream processor). [One or more pints can also serve double duty, for example, to control mode and to use one of the pins during a calibration mode for temporary receive of a heater control signal.] Many other structural configurations are also possible and will also naturally occur to those having ordinary skill in the art.

While this deployment and/or characterization can be performed at time of integrated circuit manufacture, it is also possible to perform these actions (1) at later digital device manufacture, that is, when a board or larger-scale digital device is being assembled, using previously manufactured integrated circuits, and/or (2) post-distribution of such a digital device. Other alternatives and variation will naturally occur to those having ordinary skill in the art.

FIG. 12A shows such an embodiment 1201; as indicated by a legend in the FIG., this embodiment can represent a die, an IC (e.g., having one or more dies, packaged or otherwise), or another, downstream digital device. As variously indicated by hardware blocks in this die/IC/device, the device has a resonator and/or MEMS device. Further, a flexible suspension mount is also present, optionally with a release or protection element (e.g., which permits selective or delayed deployment of the flexible suspension mount, so as to retard creep and/or shift attributable to manufacturing stress). The device also has a temperature sensor, which can be a first or second MEMS device, depending on embodiment. A built-in heating element is then used for thermal characterization; optionally, such a built-in heating element can be also or instead used for run-time operation, e.g., to instantiate an oven-controlled device (e.g., an oven-controlled oscillator or “OCXO”). The device also includes one or more of drive, sense and/or correction circuitry; in this regard, it was earlier mentioned that a two-die or three-die device can feature one die manufactured to include MEMS elements (e.g., a resonator and/or temperature sensor) and other dies which respectively implement CMOS and/or BiCMOS circuitry). Such an implementation is encompassed by the embodiment 1201 seen in the FIG., i.e., an IC can include two or more co-packaged dies, as a non-limiting example. As also seen in the FIG., the device also in some embodiments has a memory to store temperature correction data for use in processing a device output so as to be temperature invariant. Finally, as indicated at the right side of the FIG., the depicted embodiment 1201 also advantageously includes an interface (e.g., a four-pin interface), such as by way of example, where a first pin is used to output an electrical signal (e.g., generated clock and/or a sensor signal) and a second pin is used to output stored correction factors. Once again, it should be understood that each of these feature are optional and are not required for any given implementation. In an embodiment featuring MEMS components on one die, the depicted heating element can be in close proximity thereto (e.g., either part of that same die itself, or abutting that die, for example, in a sealed chamber, or “oven”).

FIG. 12B shows a series of method steps which may be used with structures introduced in connection with FIG. 12A. A method, generally referenced by numeral 1221, starts with fabrication of and/or other provision of a flexible suspension mount including a release and/or protection structure; this is referenced by numeral 1223. The flexible suspension mount (e.g., including any mounted die) is then mounted on a substrate, per numeral 1225; because the suspension structure is in compressed state (or otherwise as not been subject to prestress techniques discussed herein), its operation may experience manufacturing-induced perturbation, which can potentially ship performance conditions if left unchecked. As indicated by numeral 1227, at some point, however, the prestress, release and/or protection structures called for by this disclosures are activated or removed, as appropriate, to change flexible suspension parameters to a state intended for normal, steady-state operation. Per numeral 1229, once this milestone has been reached, the device is then thermally characterized, optionally using, for example, an on-board heating structure and onboard temperature sensor, as was described for FIG. 12A. As part of this characterization, as indicated by numeral 1231, device performance is measured as a function of temperature, and any learned correction factors derived from output variation are then programmed into the device or IC, per numeral 1231. With learned correction factors being based on steady-state deployment, the device can then either perform correction in accordance with those factors, e.g., as indicated by reference block 1233, or it can output those factors for downstream consumption and usage, as indicated above.

Reflecting on the various embodiments discussed above, what has been described are techniques for providing a flexible suspension mount for an electronic component that is sensitive to mechanical vibration. In one embodiment, the component can be a resonator and/or a MEMS device of some sort. This is to say, one implementation features these techniques used with a resonator that is not a MEMS device such as a quartz crystal oscillator; a different implementation features another type of component, such by way of nonlimiting example, an electromechanical component. Such a component can optionally be a MEMS device, such as an accelerometer, a gyroscope, a pressure sensor, a temperature sensor, or a different type of device. These devices are optionally, but not necessarily, based on MEMS resonators; as an example, it is possible to have a pressure sensor that is based on a MEMS resonator device (see, e.g., U.S. Pat. No. 11,218,984), and it is also possible to have a MEMS pressure sensor that is not based on operation of a MEMS resonator (e.g., that utilizes a deflecting membrane). A flexible suspension mount is used to the electronic component from the effects of outside mechanical disturbances, while still providing mechanical support and electrical interconnection. In one embodiment, an expanding structure and/or release structure can be used to trigger a shape-morphing function or other function where spring/dampening characteristics of the flexible suspension mount are configured; for example, the flexible suspension mount using this shape-morphing function can be transitioned from a first state in which it does not provide flexible suspension (e.g., it provides a relatively rigid mounting to facilitate certain remaining manufacturing, assembly, distribution or other processes) to a second state in which it then does provide flexible suspension properties, as described. Note that in some embodiments, this change in suspension state is achieved simply be etching or removing a layer or temporary structure of some type. In yet another nonlimiting example, such a structure can be used to prestress a flexible suspension mount. This type of activation and/or configuration is optionally performed at a selected or selective time in some embodiments. For example, it can be performed after integrated circuit manufacture, after device assembly, or at some other milestone in a manufacturing and/or product assembly and/or distribution process. Some embodiments rely on specific methods of performing device characterization and/or programming; for example, instead of probing a die at the factory and loading temperature change coefficients while manufacturing and/or assembly and/or distribution steps still remain, in one embodiment, this characterization and/or programming is performed only after flexible suspension mount deployment, i.e., such that occurs after manufacturing stresses have already been incurred.

As should be appreciated, by providing schemes for mitigating disturbance-induced creep and/or interfering vibrational stress, the techniques provided by this disclosure result in designs which can produce more accurate device operation and a more efficient manufacturing process.

As noted earlier, the various elements discussed above can be used in any desired permutation or combination, as pertinent to a specific design application at issue; the selection of suitable structures for any given implementation is within the level of ordinary skill in the art.

It should be noted that several specific terms are used in the description above. Firstly, it should be understood that contemplated embodiments can include “hardware logic,” “circuits” or “circuitry” (each meaning one or more electronic circuits). Generally speaking, these terms can include analog and/or digital circuitry, and can be special purpose in nature or general purpose. For example, as used herein, the term “circuitry” for performing a particular function can include one or more electronic circuits that are either “hard-wired” (or “dedicated”) to performing the stated function (i.e., in some cases without assistance of instructional logic), and the term can also include a microcontroller, microprocessor, FPGA or other form of processor which is general in design but which runs software or firmware (e.g., instructional logic) that causes or configures general circuitry (e.g., configures or directs a circuit processor) to perform the particular function. Note that as this definition implies, “circuits” and “circuitry” for one purpose are not necessarily mutually-exclusive to “circuits” or “circuitry” for another purpose, e.g., such terms indicate that one or more circuits are configured to perform a function, and one, two, or even all circuits can be shared with “circuitry” to perform another function (indeed, such is often the case where the “circuitry” includes a processor); this is to say, “circuitry to perform (function X)” and “circuitry to perform (function Y)” can encompass exactly the same circuitry or respective circuits, depending on implementation. Related to these points, the term “logic” encompasses hardware logic, instructional logic, or both. Instructional logic can be code written or designed in a manner that has certain structure (architectural features) such that, when the code is ultimately executed, the code causes the one or more general purpose machines (e.g., a processor, computer or other machine) each to behave as a special purpose machine, having structure that necessarily performs described tasks on input operands in dependence on the code to take specific actions or otherwise produce specific outputs. Throughout this disclosure, various processes have been described, any of which can generally be implemented as instructional logic (e.g., as instructions stored on non-transitory machine-readable media or other software logic), as hardware logic, or as a combination of these things, depending on embodiment or specific design. “Non-transitory” machine-readable or processor-accessible “media” or “storage” to the extent used herein means any tangible (i.e., physical structure) storage medium, irrespective of the type of technology used to express data on that medium or the format of data storage; for example, it can include optical, magnetic, electronic, resistive and/or other storage technologies where some type of physical device, including without limitation, random access memory, hard disk memory, optical memory, a floppy disk, a CD, a solid state drive (SSD), server storage, volatile memory, and/or nonvolatile memory, is used as a physical medium for storage. Each such medium and/or storage device can be in standalone form (e.g., a program disk or solid state device) or embodied as part of a larger mechanism, for example, resident memory that is part of a chip-card, dongle, laptop computer, portable device, server, network, printer, or other set of one or more devices; for example, such medium can comprise a network-accessible device or something that is selectively connected to a computing device, which is then read. “Instructions,” if used, can be implemented in different formats, for example, as metadata that when called is effective to invoke a certain action, as Java code or web scripting, as code written in a specific programming language (e.g., as C++ code), as a processor-specific instruction set, or in some other form; the instructions can also be executed by the same processor, different processors or processor cores, FPGAs or other configurable circuits, depending on embodiment. Depending on implementation, the instructions can be executed by a single computer and, in other cases, can be stored and/or executed on a distributed basis, e.g., using one or more servers, web clients, or application-specific devices.

In connection with various embodiments herein, the term “device” is used to refer to an electronic product (e.g., based in, but not limited to, a chip, system, or board) with circuitry and possibly, but not necessarily, resident software or firmware; examples of a device include, without limitation, an end consumer product, a computer, a smart phone, an integrated circuit, a die, and/or other manifestations. The term “integrated circuit” (or “IC”) typically refers to a structure having at least one die, packaged or otherwise, and, as stated, an IC can also be a type of device. The term “MEMS” refers to electromechanical structures that are used at the circuit board, die, IC or similar level, regardless of whether such are characterizes as miniature, “micro,” “nano,” or otherwise in terms of scale. “Substrate” as used herein refers to any structure that is conventionally used to support an electronic circuit and/or electronic device, e.g., it can include a wafer, a die, an IC or some other structure that can act as a support for these or the other elements described herein, typically also providing for electrical routing and connection to the supported element(s). “Flexible suspension mount” or “mounting” refers to the structures described herein in either isolated or group format; for example, FIGS. 4A-4C were used to describe electrical interconnections that operate as springs, in addition to providing for electrical interconnect, and the term “flexible suspension mount” can refer to either a structure associated with a single isolated one of these leads (i.e., for a given electrical signal), or for a mounting comprising all four of the depicted electrical interconnections, depending on context.

The circuits and techniques described above may be further constructed using automated systems that fabricate dies and/or integrated circuits, and may be described as instructions on non-transitory media that are adapted to control the fabrication of such integrated circuits. For example, the components and systems described may be designed as one or more integrated circuits, or a portion(s) of an integrated circuit, based on design control instructions for doing so with circuit-forming apparatus that controls the fabrication of the blocks of the integrated circuits. The instructions may be in the form of data stored in, for example, a computer-readable medium such as a magnetic tape or an optical or magnetic disk or other non-transitory media as described earlier. Such design control instructions typically encode data structures or other information or methods describing the circuitry that can be physically created as the blocks of the integrated circuits. Although any appropriate format may be used for such encoding, such data structures are commonly written in Caltech Intermediate Format (CIF), Calma GDS II Stream Format (GDSII), or Electronic Design Interchange Format (EDIF), as well as high level description languages such as VHDL or Verilog, or another form of register transfer language (“RTL”) description. Those of skill in the art of integrated circuit design can develop such data structures from schematic diagrams of the type detailed above and the corresponding descriptions and encode the data structures on computer readable medium. Those of skill in the art of integrated circuit fabrication can then use such encoded data to fabricate integrated circuits comprising one or more of the circuits described herein.

In the foregoing description and in the accompanying drawings, specific terminology and drawing symbols are set forth to provide a thorough understanding of the present technology. In some instances, the terminology and symbols may imply specific details that are not required to practice the technology. For example, although the terms “first” and “second” have been used herein, unless otherwise specified, the language is not intended to provide any specified order but merely to assist in explaining elements of the technology. In some instances, the terminology and symbols may imply specific details that are not required to practice those embodiments. The terms “exemplary” and “embodiment” are used to express an example, not a preference or requirement. Moreover, although the technology herein has been described with reference to particular embodiments, it is to be understood that these embodiments are merely illustrative of the principles and applications of the technology. It is therefore to be understood that numerous modifications may be made to the illustrative embodiments and that other arrangements may be devised without departing from the spirit and scope of the technology.

As noted earlier, various documents have been incorporated into this disclosure by reference. The definitions provided by this disclosure are to control (i.e., predominate over any definitions in the incorporated by reference documents) in the event of any inconsistency or conflict, implicit or otherwise, with the meaning of terms as used in this document.

Various modifications and changes may be made to the embodiments presented herein without departing from the broader spirit and scope of the disclosure. Features or aspects of any of the embodiments may be applied, at least where practicable, in combination with any other of the embodiments or in place of counterpart features or aspects thereof, and each is to similarly be considered “optional” as to any embodiment. Accordingly, the features of the various embodiments are not intended to be exclusive relative to one another, and the specification and drawings are to be regarded in an illustrative rather than a restrictive sense.

We claim:

1. A device, comprising:
a die;
a microelectromechanical systems (MEMS) structure on the die, the MEMS structure to deflect or vibrate during operation of the device;
at least one electrical contact to output a signal during operation of the device where the signal varies according to deflection or vibration of the MEMS structure;
wherein the MEMS structure and the at least one electrical contact are operatively coupled by a flexible suspension mount, the flexible suspension mount having a first state and a second state, and wherein the device comprises at least one structure to cause the flexible suspension mount to selectively transition from the first state to the second state; and
wherein the flexible suspension mount is such that second state and the first state have different, associated spring constants and respective, associated dampening coefficients.

2. The device of claim 1 wherein the second state is to provide a suspension frequency for the MEMS structure that is between fifty kilohertz and ninety kilohertz.

3. The device of claim 1 wherein the device further comprises a substrate and an electronic component, the die being operatively coupled to the substrate via the at least one electrical contact, wherein the electric component has an associated vibrational frequency, and wherein the second state is to provide a suspension frequency that is between two percent and twenty five percent of the associated vibrational frequency.

4. The device of claim 1 wherein the device further comprises a substrate and an electronic component, the die being operatively coupled to the substrate via the at least one electrical contact, wherein the electric component has an associated vibrational frequency, and wherein the second state is to provide a suspension frequency that is between ten percent and eighteen percent of the associated vibrational frequency.

5. The device of claim 1 wherein the device comprises a MEMS resonator and wherein the MEMS structure comprises a resonating body having doped crystalline silicon.

6. The device of claim 5 wherein the MEMS resonator is a piezoelectric resonator.

7. The device of claim 1 embodied as an oscillator, wherein the at least one electrical contact is to provide an oscillation signal which is dependent on vibration of the MEMS element.

8. The device of claim 1 wherein the device further comprises a temperature sensor on the die and wherein the least one electrical contact comprises a first electrical contact to receive impetus to drive the MEMS element, a second electrical contact to provide a sensed output, and a third electrical contact to output a temperature signal based on temperature sensed by the temperature sensor.

9. The device of claim 1 wherein the at least one structure to cause the flexible suspension mount to selectively transition from the first state to the second state comprises a selectively-expanded material.

10. The device of claim 1 wherein the at least one structure to cause the flexible suspension mount to selectively transition from the first state to the second state comprises a sacrificial layer that is to be selectively etched or removed.

11. The device of claim 1 wherein the at least one structure to cause the flexible suspension mount to selectively transition from the first state to the second state comprises a release layer that maintains compression of the flexible suspension mount while in the first state and wherein, in the second state, the release layer no longer maintains compression of the flexible suspension mount.

12. The device of claim 1 wherein the device further comprises a substrate, the flexible suspension mount mechanically coupling the die to the substrate, and wherein the die and the substrate and the flexible suspension mount are copackaged.

13. The device of claim 12 wherein the die is a first die and wherein the device includes a second die.

14. The device of claim 13 wherein the second die is the substrate.

15. The device of claim 13, embodied as an integrated circuit, wherein the second die comprises circuitry to generate an output signal of the integrated circuit, the output signal dependent on the deflection or vibration of the MEMS structure.

16. The device of claim 15 wherein the device further comprise a temperature sensor, wherein the circuitry comprises storage for temperature correction information, and wherein the temperature correction information is for use in correcting a temperature-dependent variation of the MEMS element.

17. The device of claim 16 wherein the circuitry is to generate the output signal of the integrated circuit as a temperature-corrected output in dependence on the stored temperature correction information.

18. The device of claim 16 wherein the integrated circuit is to output the temperature correction information as well as a temperature signal.

19. The device of claim 16 wherein the device further comprises a heating element that is to be selectively controlled in order to generate the temperature correction information.

20. The device of 18 embodied as an oscillator integrated circuit, wherein the flexible suspension mount comprises at least one metallic structure that is to carry a sensed signal that varies according to a resonant vibration of the MEMS structure.
